(19) United States
(12) Patent Application Publication
(10) Pub. No.: US 2026/0248239 A1
(43) Pub. Date: Aug. 27, 2026

(54) METHODS, APPARATUSES, AND SYSTEMS FOR GENERATING INSOLES

(71) Applicant: Groov, Lake Success, NY (US)

(72) Inventor: Daniel Cataldi, Lake Success, NY (US)

(21) Appl. No.: 19/566,567

(22) Filed: Mar. 13, 2026

Related U.S. Application Data
(63) Continuation-in-part of application No. 18/646,361, filed on Apr. 25, 2024.
(60) Provisional application No. 63/498,310, filed on Apr. 26, 2023.
(60) Provisional application No. 63/606,366, filed on Dec. 5, 2023.

(51) Int. Cl. A43B 17/18; A43B 7/1405; A43B 9/00; A43D 1/02; G06F 30/10

(52) U.S. Cl. CPC A43B 17/18; A43B 7/141; A43B 9/00; A43D 1/02; G06F 30/10

(57) ABSTRACT

Methods, apparatuses, and systems are described for scanning feet of an individual for generating insoles for shoes of the individual. The individual may create a profile for storing information associated with the individual, including shoe information and the scans of the feet of the individual. The insoles may be generated based on the scans of the feet of the individual in addition to the shoe information.

### CROSS REFERENCE TO RELATED PATENT APPLICATIONS

This application is a continuation-in-part to U.S. non-provisional patent application Ser. No. 18/646,361, filed on Apr. 25, 2024, which claims priority to U.S. Provisional Patent Application No. 63/498,310, filed on Apr. 26, 2023, and to U.S. Provisional Patent Application No. 63/606,366, filed on Dec. 5, 2023, which are hereby incorporated by reference in their entirety.

### BACKGROUND

Shoe footbeds/insoles, or inserts, are useful for several purposes such as improving daily wear comfort, height enhancement, plantar fasciitis treatment, arch support, foot and joint pain relief from arthritis, preventing overuse, mitigating injuries, assisting in leg length discrepancy, assisting in the recovery from orthopedic correction, and providing assistance in performing athletic activities. Essentially, shoe insoles help treat and prevent foot motion and/or gait problems that affect a person's soles, ankles, knees, hips, back, etc., especially while performing athletic activities where the load on the feet is many times the weight of the individual's body. Shoe insoles designed for athletic use are useful for supporting and stabilizing the foot, as well as for providing additional shock absorption in order to reduce the load on joints. However, ready-made footwear, including footwear insoles, are not customized for individual consumers. Moreover, conventional methods for producing custom footwear typically involve expensive, time-consuming processes that require specialized equipment and skilled technicians. These methods often result in products that are prohibitively costly for most consumers and cannot be efficiently scaled for mass production. Additionally, existing custom footwear solutions generally produce complete shoes that cannot be easily modified or updated, limiting their adaptability to changing user needs or preferences. The integration of digital scanning technologies with footwear design has shown promise, but existing systems suffer from several technical limitations. Many scanning methods fail to capture adequate positional data to account for the dynamic nature of foot movement and loading conditions. Furthermore, current quality control processes for digital foot scans are often manual and subjective, leading to inconsistent results and the need for costly re-scanning procedures. Although modular footwear systems have emerged as a potential solution to provide customization flexibility, existing approaches lack the integration of personalized biomechanical components. Conventional modular systems typically focus on aesthetic customization rather than addressing the fundamental fit and support requirements that vary significantly between individuals.

### SUMMARY

It is to be understood that both the following general description and the following detailed description are exemplary and explanatory only and are not restrictive.

Methods, systems, and apparatuses for improved scanning of an individual's feet, footwear, gait, or other footwear-related entities for generating insoles/footbeds and other personalized footwear-related solutions are described. A data capture device (e.g., smartphone, camera, tablet computer, etc.) connected to a network may generate and/or maintain image scans of an individual's feet for generating custom footbed designs and producing custom footbeds according to the custom footbed designs. Each foot of an individual may be scanned (e.g., 3-D images) using the data capture device. Customized footbeds may be generated (e.g., produced) based on the scans of the individual's feet. The scans may be stored in a user profile associated with the individual or a group of individuals. The user profile may also store data associated with shoes of the individual that may be used in addition to the scans of the individual's feet to generate footbed designs for producing footbeds that are tailored to the individual's feet and to fit a specific shoe of the individual. In addition, modular footwear systems may be produced that include an upper component and outsole component designed to fit the custom footbeds and attach to the custom footbeds via attachment interfaces along a perimeter of the footbeds. These modular footwear systems, including the customized footbeds, may be produced by a distributed fulfillment system that is designed to utilize a digital-to-physical pipeline that processes biometric foot data implements a distributed protocol for routing the personalized footwear components to appropriate assembly nodes based on manufacturing capabilities and delivery requirements.

In an embodiment, are modular footwear systems comprising a footbed comprising one or more attachment interfaces along a perimeter of the footbed, wherein the footbed is generated according to a footbed design, wherein the footbed design is generated according to individual foot characteristics captured by a plurality of scans of a user foot, an upper configured to couple with the footbed via the one or more attachment interfaces, and an outsole configured to couple with the footbed via the one or more attachment interfaces, wherein the footbed is configured as an anchor between the upper and the outsole.

In an embodiment, are distributed fulfillment system comprising a central order management system configured to receive one or more footbed designs, and distribute the one or more footbed designs to one or more footbed manufacturing locations, the one or more footbed manufacturing locations configured to, produce, based on the one or more footbed designs, one or more footbeds, and distribute the one or more footbeds to one or more brand manufacturing locations, and the one or more brand manufacturing locations configured to produce, based on integrating each footbed of the one or more footbeds with one or more footwear components, one or more footwear products, and distribute the one or more footwear products.

In an embodiment, are methods comprising receiving, by a device, from one or more scanning devices, a plurality of scans of a user foot, receiving data indicative of one or more shoe characteristics, generating, based on data indicative of the plurality of scans, a point cloud associated with the user foot, generating, based on the point cloud, a mesh representation of the user foot, generating, based on the mesh representation of the user foot and the data indicative of the one or more shoe characteristics, a footbed design, and causing a production of a footbed according to the footbed design, wherein the footbed comprises one or more attachment interfaces configured to couple the footbed with one or more footwear components associated with the one or more shoe characteristics.

In an embodiment, are methods comprising receiving, by a device, from one or more scanning devices, a plurality of scans of a user foot, receiving data indicative of one or more shoe characteristics, causing, based on data associated with a first portion of the plurality of scans satisfies a threshold and data associated with a second portion of the plurality of scans does not satisfy the threshold, the second portion of the plurality of scans to be retaken until each scan of the second portion of the plurality of scans satisfies the threshold, generating, based on the first portion of the plurality of scans and the retaken second portion of the plurality of scans and based on the data indicative of the one or more shoe characteristics, a footbed design, and causing a production of a footbed according to the footbed design, wherein the footbed comprises one or more attachment interfaces configured to couple the footbed with one or more footwear components associated with the one or more shoe characteristics.

This summary is not intended to identify critical or essential features of the disclosure, but merely to summarize certain features and variations thereof. Other details and features will be described in the sections that follow.

### BRIEF DESCRIPTION OF THE DRAWINGS

The accompanying drawings, which are incorporated in and constitute a part of the present description serve to explain the principles of the apparatuses and systems described herein:

FIG. 1 shows an example system for generating customized footbeds;

FIG. 2 shows an example system for generating customized footbeds;

FIG. 3 shows an example system for generating customized footbeds;

FIG. 4 shows an example system for generating customized footbeds;

FIG. 5 shows an example process for generating customized footbeds;

FIG. 6 shows an example process for generating customized footbeds;

FIG. 7 shows a flowchart of an example scan method;

FIG. 8 shows an example system environment;

FIGS. 9A-9D show example scans of an individual's foot;

FIG. 10 shows an example operational flow of uploading groups of user profiles;

FIGS. 11A-11D show example footwear components of a modular footwear system;

FIG. 12 shows example footwear components of a modular footwear system;

FIG. 13 shows an example footbed component of a modular footwear system;

FIG. 14 shows a flowchart of an example method;

FIG. 15 shows a flowchart of an example method; and

FIG. 16 shows a block diagram of an example system and computing device.

### DETAILED DESCRIPTION

As used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another configuration includes from the one particular value and/or to the other particular value. When values are expressed as approximations, by use of the antecedent “about,” it will be understood that the particular value forms another configuration. It will be further understood that the endpoints of each of the ranges are significant both in relation to the other endpoint, and independently of the other endpoint.

“Optional” or “optionally” means that the subsequently described event or circumstance may or may not occur, and that the description includes cases where said event or circumstance occurs and cases where it does not.

Throughout the description and claims of this specification, the word “comprise” and variations of the word, such as “comprising” and “comprises,” means “including but not limited to,” and is not intended to exclude other components, integers or steps. “Exemplary” means “an example of” and is not intended to convey an indication of a preferred or ideal configuration. “Such as” is not used in a restrictive sense, but for explanatory purposes.

It is understood that when combinations, subsets, interactions, groups, etc. of components are described that, while specific reference of each various individual and collective combinations and permutations of these may not be explicitly described, each is specifically contemplated and described herein. This applies to all parts of this application including, but not limited to, steps in described methods. Thus, if there are a variety of additional steps that may be performed it is understood that each of these additional steps may be performed with any specific configuration or combination of configurations of the described methods.

As will be appreciated by one skilled in the art, the methods and systems may take the form of an entirely hardware embodiment, an entirely software embodiment, or an embodiment combining software and hardware aspects. Furthermore, the methods and systems may take the form of a computer program product on a computer-readable storage medium having computer-readable program instructions (e.g., computer software) embodied in the storage medium. More particularly, the present methods and systems may take the form of web-implemented computer software. Any suitable computer-readable storage medium may be utilized including hard disks, CD-ROMs, optical storage devices, magnetic storage devices, memresistors, Non-Volatile Random Access Memory (NVRAM), flash memory, or a combination thereof.

Throughout this application reference is made to block diagrams and flowcharts. It will be understood that each block of the block diagrams and flowcharts, and combinations of blocks in the block diagrams and flowcharts, respectively, may be implemented by processor-executable instructions. These processor-executable instructions may be loaded onto a general purpose computer, special purpose computer, or other programmable data processing apparatus to produce a machine, such that the processor-executable instructions which execute on the computer or other programmable data processing apparatus create a device for implementing the functions specified in the flowchart block or blocks.

These processor-executable instructions may also be stored in a computer-readable memory that may direct a computer or other programmable data processing apparatus to function in a particular manner, such that the processor-executable instructions stored in the computer-readable memory produce an article of manufacture including processor-executable instructions for implementing the function specified in the flowchart block or blocks. The processor-executable instructions may also be loaded onto a computer or other programmable data processing apparatus to cause a series of operational steps to be performed on the computer or other programmable apparatus to produce a computer-implemented process such that the processor-executable instructions that execute on the computer or other programmable apparatus provide steps for implementing the functions specified in the flowchart block or blocks.

Accordingly, blocks of the block diagrams and flowcharts support combinations of devices for performing the specified functions, combinations of steps for performing the specified functions and program instruction means for performing the specified functions. It will also be understood that each block of the block diagrams and flowcharts, and combinations of blocks in the block diagrams and flowcharts, may be implemented by special purpose hardware-based computer systems that perform the specified functions or steps, or combinations of special purpose hardware and computer instructions.

This detailed description may refer to a given entity performing some action. It should be understood that this language may in some cases mean that a system (e.g., a computer) owned and/or controlled by the given entity is actually performing the action.

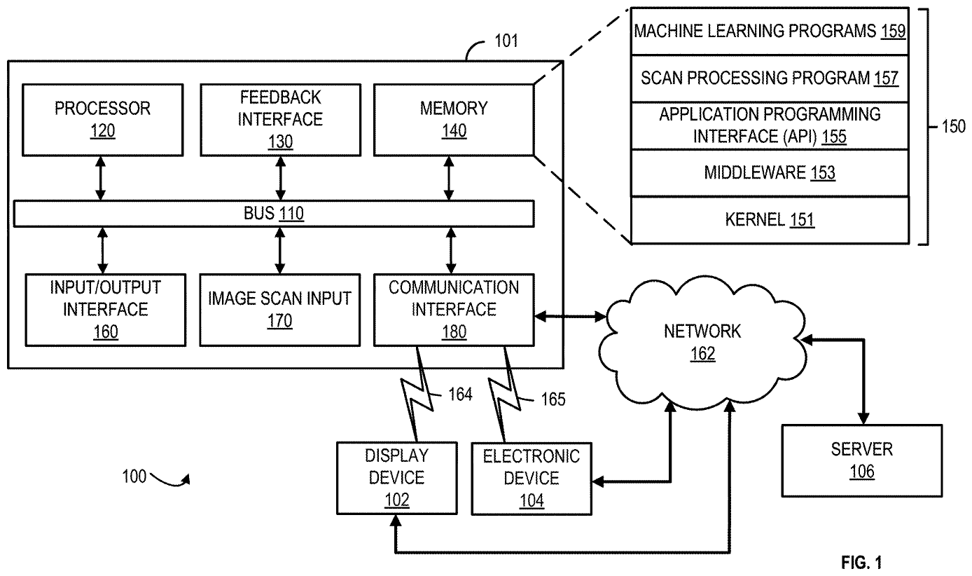

FIG. 1 shows an example system 100 for scanning and generating (e.g., producing) customized shoe footbeds/insoles. For example, a device (e.g., data capture device 101) may scan one or more of an individual's extremities (e.g., feet, hands, arms, legs, etc.). For example, the device may receive a plurality of scans of one or more of the extremities via one or more scanning devices. The scans may be retaken until each scan satisfies a quality threshold. The scans that satisfy the quality threshold may be used to generate (e.g., produce) a pair of footbeds for the individual. The system 100 may include a data capture device 101, a display device 102, an electronic device 104, and one or more servers 106. In an example, the data capture device 101 may be configured to take a plurality of scans of an individual's extremity (e.g., feet, hands, arms, legs, etc.). In an example, the data capture device 101 may be in communication with the display device 102, the electronic device 104, and the one or more servers 106 via a network (e.g., network 162).

The data capture device 101 may include a bus 110, one or more processors 120, a feedback interface 130, a memory 140, an input/output interface 160, an image scan input 170, and a communication interface 180. In certain examples, the data capture device 101 may omit at least one of the aforementioned elements or may additionally include other elements. The data capture device 101 may comprise, for example, a laptop computer, a mobile phone, a smart phone, a tablet computer, a wearable device, a smartwatch, a haptic device, a desktop computer, a smart television, and the like.

The bus 110 may comprise a circuit for connecting the bus 110, the one or more processors 120, the feedback interface 130, the memory 140, the input/output interface 160, the image scan input 170, and/or the communication interface 180 to each other and for delivering communication (e.g., a control message and/or data) between the bus 110, the one or more processors 120, the feedback interface 130, the memory 140, the input/output interface 160, the image scan input 170, and/or the communication interface 180.

The one or more processors 120 may include one or more of a Central Processing Unit (CPU), an Application Processor (AP), or a Communication Processor (CP). The one or more processors 120 may control, for example, at least one of the bus 110, the feedback interface 130, the memory 140, the input/output interface 160, the image scan input 170, and/or the communication interface 180 of the data capture device 101 and/or may execute an arithmetic operation or data processing for communication. As an example, the one or more processors 120 may drive (e.g., cause) the image scan input 170 to take/capture a plurality of scans of an individual's extremity (e.g., feet, hands, arms, legs, etc.). As an example, the one or more processors 120 may drive (e.g., cause) the feedback interface 130 to output feedback (e.g., haptic feedback, audio feedback, visual feedback, etc.) to the individual during the scanning process. For example, the feedback may indicate that the data capture device 101 is continuing to collect data (e.g., scanning data), real-time course-correction indicators as the individual scans the extremity, the scanning process terminated based on an error during the scanning process, and/or the scanning process has completed. The processing (or controlling) operation of the one or more processors 120 according to various embodiments is described in detail with reference to the following drawings.

The processor-executable instructions executed by the one or more processors 120 may be stored and/or maintained by the memory 140. The memory 140 may include a volatile and/or non-volatile memory. The memory 140 may include random-access memory (RAM), flash memory, solid state or inertial disks, or any combination thereof. As an example, the memory 140 may include an Embedded MultiMedia Card (eMMC). The memory 140 may store, for example, a command or data related to at least one of the bus 110, the one or more processors 120, the feedback interface 130, the memory 140, the input/output interface 160, the image scan input 170, and/or the communication interface 180 of the data capture device 101. According to various examples, the memory 140 may store software and/or a program 150 or may comprise firmware. For example, the program 150 may include a kernel 151, a middleware 153, an Application Programming Interface (API) 155, a scan processing program 157, and/or machine learning programs/models 159, and/or the like, configured for controlling one or more functions of the data capture device 101 and/or an external device (e.g., the display device 102 or electronic device 104). At least one part of the kernel 151, middleware 153, or API 155 may be referred to as an Operating System (OS). The memory 140 may include a computer-readable recording medium (e.g., a non-transitory computer-readable medium) having a program recorded therein to perform the methods according to various embodiments by the one or more processors 120. In an example, the memory 140 may store the scans received from the image scan input 170.

The kernel 151 may control or manage, for example, system resources (e.g., the bus 110, the one or more processors 120, the memory 140, etc.) used to execute an operation or function implemented in other programs (e.g., the middleware 153, the API 155, the scan processing program 157, or the machine learning program/model 159). Further, the kernel 151 may provide an interface capable of controlling or managing the system resources by accessing individual elements of the data capture device 101 in the middleware 153, the API 155, the scan processing program 157, or the machine learning program/model 159.

The middleware 153 may perform, for example, a mediation role, so that the API 155, the scan processing program 157, and/or the machine learning programs/models 159 can communicate with the kernel 151 to exchange data. Further, the middleware 153 may handle one or more task requests received from the scan processing program 157 and/or the machine learning programs/models 159 according to a priority. For example, the middleware 153 may assign a priority of using the system resources (e.g., the bus 110, the one or more processors 120, or the memory 140) of the data capture device 101 to at least one of the scan processing program 157 and/or the machine learning programs/models 159. For example, the middleware 153 may process the one or more task requests according to the priority assigned to at least one of the application programs, and thus, may perform scheduling or load balancing on the one or more task requests.

The API 155 may include at least one interface or function (e.g., instruction), for example, for file control, window control, video processing, and/or character control, as an interface capable of controlling a function provided by the scan processing program 157 and/or the machine learning program/model 159 in the kernel 151 or the middleware 153.

As an example, the scan processing program 157 and the machine learning programs/models 159 may be independent of each other or integrally combined, in whole or in part.

The scan processing program 157 may include logic (e.g., hardware, software, firmware, etc.) that may be implemented to process the scans taken by the image scan input 170 in order to generate footbed designs that may be used to produce customized footbeds. The image scan input 170 may comprise an image sensor, a camera, a depth/motion capture sensor (e.g., RGB-D camera), or any device configured to take/capture scans (e.g., three-dimensional scans) of an extremity (e.g., feet, hands, arms, legs, etc.) of an individual. For example, the individual may move the data capture device 101 around the extremity (e.g., foot, hand, arm, leg, etc.) as the image scan input 170 scans the extremity and the data capture device 101 records the data collected by the image scan input 170 (e.g., storing the scans in memory 140). The scanning process may be initiated based on receiving a user input via the input/output interface 160. For example, a user may select an option, via the input/output interface 160, to activate the image scan input 170 and initiate the scanning process. In an example, the scanning process may be initiated automatically based on a positioning of an extremity (e.g., foot, hand, arm, leg, etc.) of the individual in front of the image scan input 170 after an initial activation of the image scan input 170. For example, the individual may select an option, via the input/output interface 160, to initiate the scanning process, and thus, activating the image scan input 170. The individual may place one of the individual's extremities (e.g., foot, hand, arm, leg, etc.) in front of the image scan input 170, wherein the image scan input 170 may automatically initiate the scanning process after detecting that the extremity (e.g., foot, hand, arm, leg, etc.) is in a correct position in front of the image scan input 170. For example, a certain/predetermined area and angle (e.g., position) of the individual's extremity (e.g., foot, hand, arm, leg, etc.) may be required to be detected by the image scan input 170 before the scanning process is initiated. Once the data capture device 101 determines (e.g., detects) that the required area and angle of the individual's extremity (e.g., foot, hand, arm, leg, etc.) is captured by the image scan input 170, the scanning process may automatically begin.

The scans may be collected by both a visible light camera and an infrared depth-mapping system of the image scan input 170. In an example, the scans may be collected based on one or more of an infrared dot blotter, a gyroscope, a light detection and ranging (LiDAR) sensor, etc. As an example, the scans may comprise outside (e.g., lateral arch) and/or inside (e.g., medial arch) portions of the individual's extremity (e.g., foot, hand, arm, leg, etc.). As an example, the image scan input 170 may capture data indicative of one or more positions of the extremity (e.g., foot, hand, arm, leg, etc.) as the individual walks in front of the image scan input 170. For example, the data capture device 101 (e.g., the scan processing program 157) may be configured to include computer vision gait analysis logic that may be implemented to analyze the individual's gait. The data capture device 101 may perform a gait analysis (e.g., supination/pronation assessment) of the individual as the individual walks in front of the image scan input 170 (e.g., towards the image capture input 170 and/or laterally across the image scan input 170) of the data capture device 101. As an example, as the data capture device 101 receives the scans, the data capture device 101 may provide feedback (e.g., haptic feedback, audio feedback, visual feedback, etc.) via the feedback interface 130. The feedback may indicate that the data capture device 101 is continuing to collect data, real-time course-correction indicators as the individual scans the extremity, the scanning process terminated based on an error during the scanning process, and/or the scanning process has completed. In an example, an object mapping program may operate in unison with the machine learning programs/models 159 during the recording process to identify when a threshold amount of data across relevant regions/portions of the individual's extremity (e.g., foot, hand, arm, leg, etc.) has been collected.

The scan processing program 157 may be further configured to determine whether each scan of the completed scans satisfy a quality threshold. For example, the scan processing program 157 may cause the data capture device 101 to process each scan of a plurality of scans received via the image scan input 170 to determine that data associated with a first one or more scans (e.g., first portion) of the plurality of scans satisfies the quality threshold and that data associated with a second one or more scans (e.g., second portion) of the plurality of scans do not satisfy the quality threshold.

As an example, the completed scans may be processed via the machine learning programs/models 159 to determine whether each scan satisfies the quality threshold. The machine learning programs/models 159 may include logic (e.g., hardware, software, firmware, etc.) that may be implemented to process the completed scans taken by the image scan input 170. For example, the machine learning programs/models 159 may include logic comprising a plurality of machine learning models. For example, the machine learning programs/models 159 may include one or more of a segmentation model and/or a classification model. For example, the data capture device 101 may generate a point cloud associated with the user's extremity based on the plurality of scans. The segmentation model may be configured to process the completed scans to determine points of the point cloud that make up the extremity, in each scan, and remove points of the point cloud that do not make up the extremity. The segmentation model may then generate a segmented point cloud, for each scan, based on removing the points of the point cloud that do not make up the extremity. The segmented point cloud of each scan may then be sent to the classification model, wherein the classification model may determine whether each scan satisfies the quality threshold (e.g., edge clarity threshold, proper positioning threshold, etc.). In an example, the point cloud may be converted to a computer-aided design (CAD) mesh, or mesh representation, of the extremity. The mesh representation may be sent to the classification model, wherein the classification model may determine whether the associated scan satisfies the quality threshold (e.g., edge clarity threshold, proper positioning threshold, etc.). The scans that do not satisfy the quality threshold may then be retaken until the scans satisfy the quality threshold. In an example, the scans that do not satisfy the quality threshold may be stored for further labeling to be used as training data for the machine learning programs/models 159. For example, the scans that do not satisfy the quality threshold may be stored in the memory 140 or may be sent to the sever 106 and stored in one or more databases of the server 106.

The completed scans, including the retaken scans, that satisfy the quality threshold may be stored in a user profile associated with the individual. In an example, the point clouds may be converted to a CAD mesh (e.g., mesh representation), wherein the CAD mesh of each scan may be stored in the user profile associated with the individual. For example, the individual may create a user profile for storing the scans to be used for creating/producing footbeds/insoles for the individual. The user profile may be stored in a database, such as a database of the server 106. The scan processing program 157 may cause the data capture device 101 to generate a footbed design based on the first one or more scans and the retaken second one or more scans, wherein a footbed may be produced according to the footbed design. For example, the footbeds may be designed and produced according to individual feet characteristics captured by the plurality of scans of the individual's feet.

In an example, the individual may store specific shoes in the user profile. As an example, footbeds may be created/produced (e.g., customized) for each of the individual's shoes stored in the individual's user profile. For example, the data capture device 101 may receive data indicative of one or more shoe characteristics, wherein the footbeds may be deigned according to the one or more shoe characteristics. As an example, the footbeds may be produced such that an outside edge of the footbeds match exactly to the perimeter of the shoes' internal lasts in order to provide a perfect fit for the individual according to the individual's shoes. In an example, the footbeds may comprise one or more attachment interfaces configured to couple the footbeds with one or more footwear components designed according to the one or more shoe characteristics. The data indicative of the one or more shoe characteristics may comprise one or more of data indicative of one or more scans of an interior of a shoe, data indicative of an interior shape of the shoe, data indicative of one or more scans of the footbed designed to fit in the shoe, data indicative of a shape of the footbed designed to fit in the shoe, data indicative of a shoe height, data indicative of a shoe width, or data indicative of a shoe material. For example, the footbeds may be designed according to individual feet characteristics captured by the plurality of scans of the individual's feet to fit in the individual's shoes.

In an example, the data capture device 101 may capture scans of the individual's shoes and/or sock liners of the individual's shoes. The footbeds may be produced such that the outside edge of the footbeds align to a perimeter of the sock liners (e.g., prefabricated footbeds) of the shoes.

In an example, the individual may input additional user information to the user profile. For example, the additional information may comprise one or more of a height, a weight, a desired length of the pair of footbeds to be produced, a desired upper material, or an identifier of the pair of footbeds to be produced. The additional information may be used to further customize the footbeds for the individual. In an example, a self-augmenting fit profile based on a computer vision wear assessment may be implemented by the scan processing program 157 by scanning a pair of footbeds of the individual that have been worn by the individual for a period of time (e.g., days, weeks, months, years, etc.). The fit profile may be stored in the individual's profile to be used with the one or more scans of an individual's feet for further enhancing the design of the individual's footbeds. For example, footbeds may be produced/created based on the plurality of scans and the fit profile of the individual.

In an example, one or more shoe designs may be generated based on the footbeds and/or based on the scans of the individual's feet. For example, one or more types of shoe designs (e.g., sneakers, dress shoes, high heel shoes, running shoes, soccer shoes, football shoes, etc.) may be generated based on the footbeds and/or based on the scans of the individual's feet. One or more shoes may be produced based on the one or more shoe designs. As example, a modular footwear system comprising one or more footwear components may be designed and produced based on the footbeds. For example, the one or more footwear components of the modular footwear system may comprise the footbed produced based on the plurality of scans, an upper component, and an outsole component. The footbed may further comprise one or more attachment interfaces along a perimeter of the footbed. The one or more attachment interfaces may comprise one or more dual-axis locking tabs configured to provide fore-aft and lateral stability between the footbed and the upper component, one or more magnetic aligners configured to align the footbed with the upper component, one or more adaptive fit anchors (e.g., elastic loops) configured to allow an individual wearing the modular footwear system to tension the upper component, and/or one or more anti-rotation features configured to prevent slippage under load (e.g., a person standing up). The one or more magnetic aligners may comprise one or more RFID-based placement guides configured to provide real-time assembly guidance and component verification. The one or more anti-rotation features may comprise one or more key-and-slot designs. The upper component may be configured to couple to a top portion of the footbed via the one or more attachment interfaces. In addition, the outsole component may be configured to couple to a bottom portion of the footbed via the one or more attachment interfaces. In an example, the footbed may further comprise one or more perimeter dovetails (e.g., magnetic alignment wells) configured to align the footbeds with the upper component and the outsole component. In an example, the footbed, the upper component, and/or the outsole component may comprise one or more embedded near field communication (NFC) tags and/or QR coding. For example, the footbed, the upper component, and/or the outsole component may may be matched for their intended shell variants based on the NFC tags and/or the QR coding. In an example, the QR coding may be used to link a modular footwear system and/or one of its footwear components (e.g., the footbed, the upper component, and/or the outsole component) to the individual (e.g., user profile) and/or order metadata. As an example, the footbed, the upper component, and/or the outsole component may be matched to each other based on the one or more embedded NFC tags and/or the QR coding. The shoe, or the modular footwear system, designs (e.g., according to one or more types of shoes designs) may be stored in the user profiled of the individuals. The shoe, or modular footwear system, designs may be sent to one or more manufactures or shoe producers, wherein one or more shoes, or modular footwear systems, may be produced based on one or more of the shoe, or modular footwear system, designs. The generated shoe, or modular footwear system, designs may enable individual customers to receive consistent and optimized shoes, or modular footwear systems, (e.g., customized shoes) across one or more different types of footwear, brands, shoe sizes, and models. In addition, the generated shoe, or modular footwear system, designs may combine on-demand manufacturing of the footbed with just-in-time assembly of the shoe, or modular footwear system, based on the footbed.

The input/output interface 160 may include an interface for delivering an instruction or data input from the individual (e.g., an operator of the data capture device 101) or from a different external device (e.g., electronic device 104) to the different elements of the data capture device 101. The input/output interface 160 may further include an interface for outputting one or more user interfaces to the individual. For example, the input/output interface 160 may comprise a display, such as a touch screen display, and/or one or more physical input interfaces (e.g., keyboard, mouse, etc.) configured to receive user inputs. The input/output interface 160 may be configured to output (e.g., display) a first user interface comprising one or more options for initiating the scanning process of an extremity (e.g., foot, hand, arm, leg, etc.) of the individual. In an example, the first user interface may be based on the user profile of the individual. For example, the first user interface may include previously completed scans of one or more extremities of the individual and/or shoes, or modular footwear systems, previously uploaded by the individual. In an example, the first user interface may include an option to view instructional content before initiating the scanning process. In an example, the one or more options may include an option for an assisted scanning process and/or an unassisted scanning process. For example, based on a selection of at least one of the one or more options (e.g., the assisted scanning process option, the unassisted scanning process option, etc.), the scanning interface may output (e.g., display) instructions to the individual for positioning of the extremity as the extremity is being scanned.

The individual may select an option to activate one or more scanning devices (e.g. image scan input 170) and initiate the scanning process. In an example, the scanning process may be initiated automatically based on a positioning of an extremity (e.g., foot, hand, arm, leg, etc.) of an individual in front of the image scan input 170 after an initial activation of the image scan input 170. For example, the individual may select an option, via the input/output interface 160, to initiate the scanning process, and thus, activating the image scan input 170. The individual may place one of the individual's extremities (e.g., foot, hand, arm, leg, etc.) in front of the image scan input 170, wherein the image scan input 170 may automatically initiate the scanning process after detecting that the extremity (e.g., foot, hand, arm, leg, etc.) is in a correct position in front of the image scan input 170. For example, a certain/predetermined area and angle (e.g., position) of the individual's extremity (e.g., foot, hand, arm, leg, etc.) may be required to be captured by the image scan input 170 before the scanning process is initiated. Once the data capture device 101 determines (e.g., detects) that the required area and angle of the individual's extremity (e.g., foot, hand, arm, leg, etc.) is captured by the image scan input 170, the scanning process may automatically begin. The input/output interface 160 may output (e.g., display) a scanning device interface. The scanning device interface may be configured to output (e.g., display) the extremity (e.g., foot, hand, arm, leg, etc.) of the individual as the extremity is being scanned according to the scanning process or as the extremity is captured for initiating the scanning process. For example, the input/output interface 160 may output (e.g., display) a visual intake (e.g., three-dimensional scan/image) of the extremity as the extremity is being scanned/captured. In an example, the data capture device 101 may include an infrared dot-blotter within a TrueDepth Camera system (e.g., the image scan input 170). The individual may provide input via the scanning device interface (e.g., via a touch screen interface or one or more physical buttons) to execute each scan of the extremity. The data capture device 101 may receive, via the image scan input 170, a plurality scans for each extremity of the individual and record the scans in the memory 140 and/or may send the scans to the server 106 to be stored in one or more databases in the individual's user profile. For example, the image scan input 170 may scan the individual's extremity as the individual moves the data capture device 101 in a specified motion based on specific areas of coverage around the extremity. In an example, the data capture device 101 may provide feedback (e.g., haptic feedback, audio feedback, visual feedback, etc.), via the feedback interface 130 as the individual scans the extremity. For example, the feedback may indicate that the data capture device 101 is continuing to collect data (e.g., scanning data), real-time course-correction indicators as the individual scans the extremity, the scanning process terminated based on an error during the scanning process, and/or the scanning process has completed.

Based on the plurality of scans, the image scan input 170 may output (e.g., display) a second user interface comprising one or options for producing a pair of footbeds. For example, the image scan input 170 may output the one or more options after the scanning process is completed. The one or more options for producing the pair of footbeds may comprise a general-purpose shape option or a shoe-specific shape option. Based on a selection of the shoe-specific shape option, a third user interface may be output to the individual. As an example, the third user interface may be configured to display instructions for the individual to scan a shoe, a sock liner, or a footbed (e.g., a prefabricated footbed) designed to fit in one or more shoes. For example, the data capture device 101 may receive data indicative of one or more scans of an interior of a shoe, data indicative of an interior shape of the shoe, data indicative of one or more scans of the footbed designed to fit in the shoe, data indicative of a shape of the footbed designed to fit in the shoe, data indicative of a shoe height, data indicative of a shoe width, or data indicative of a shoe material. In one example, the footbeds may be designed and produced such that the outside edge of the footbeds match exactly to the perimeter of the shoes' internal lasts in order to provide a perfect fit for the individual for the individual's shoes. In another example, the footbed may be designed and produced such that the outside edge of the footbeds align to a perimeter of the sock liners, or prefabricated footbeds, of the shoes. As an example, the third user interface may be configured to receive user input associated with additional information of the user. The additional information may comprise one or more of a height, a weight, a desired length of the pair of footbeds to be produced, a desired upper material, or an identifier of the pair of footbeds to be produced. In an example, based on the selection of the shoe-specific shape option, the pair of footbeds may be produced according to the plurality of scans and the data associated with the one or more shoes associated with the individual.

In an example, an additional user interface may be provided for producing one or more pairs of shoes, such as one or more modular footwear systems. The one or more pairs of shoes, or modular footwear systems, may be produced based on the generated footbed/sock liner, based on scans of the individual's shoes, based on one or more shoe characteristics, and/or based on the scans of the individual's feet. In addition, the one or more pairs of shoes, or modular footwear systems, may be generated based on one or more of the height, the weight, the desired length of the pair of footbeds to be produced, or the desired upper material. For example, one or more shoe designs, or modular footwear system designs, may be generated based on the footbeds/scans associated with the individual's feet/shoes and/or based on one or more of the height, the weight, the desired length of the pair of footbeds to be produced, or the desired upper material. The shoe, or modular footwear system, designs (e.g., according to one or more types of shoes designs) may be stored in the user profiled of the individual. The shoes, or modular footwear system, designs may be sent to one or more manufactures or shoe producers, wherein one or more shoes, or modular footwear systems, may be produced based on one or more of the shoe, or modular footwear system, designs.

In an example, the input/output interface 160 may output an instruction or data received from one or more elements of the data capture device 101 to one or more external devices (e.g., display device 102 or electronic device 104).

The communication interface 180 may establish, for example, communication between the data capture device 101 and one or more external devices (e.g., the display device 102, the electronic device 104, and/or the server 106). For example, the communication interface 180 may communicate with the one or more external devices (e.g., the display device 102, the electronic device 104, and/or the server 106) by being connected to a network 162 through wireless communication or wired communication. The network 162 may include, for example, at least one of a telecommunications network, a computer network (e.g., LAN or WAN), the Internet, and/or a telephone network.

The communication interface 180 may be configured to communicate with the one or more external devices (e.g., display device 102, or electronic device 104) via a wired communication interface 164, 165 or a wireless communication interface 164, 165. In an example, the wired communication may include, for example, at least one of Universal Serial Bus (USB), High Definition Multimedia Interface (HDMI), Recommended Standard-232 (RS-232), power-line communication, Plain Old Telephone Service (POTS), and the like. In an example, as a cellular communication protocol, the wireless communication interface 164, 165 may use at least one of Long-Term Evolution (LTE), LTE Advance (LTE-A), Code Division Multiple Access (CDMA), Wideband CDMA (WCDMA), Universal Mobile Telecommunications System (UMTS), Wireless Broadband (WiBro), Global System for Mobile Communications (GSM), and the like. In an example, the wireless communication interface 164, 165 may be configured to use a near-distance communication 164, 165. The near-distance communication interface 164, 165 may include for example, at least one of Wireless Fidelity (WiFi), Bluetooth, Bluetooth Low Energy (BLE), Near Field Communication (NFC), Global Navigation Satellite System (GNSS), and the like. According to a usage region or a bandwidth or the like, the GNSS may include, for example, at least one of Global Positioning System (GPS), Global Navigation Satellite System (GLONASS), BeiDou Navigation Satellite System (BDS), Galileo, the European global satellite-based navigation system, and the like. Hereinafter, the “GPS” and the “GNSS” may be used interchangeably in the present document. In an example, the communication interface 180 may include or be communicably coupled to a transmitter, receiver and/or transceiver for communication with the external devices (e.g., display device 102, or electronic device 104).

The display device 102 may comprise one or more of a smart television, an audio/video monitor, a streaming device, and the like. The display device 102 may include various types of displays, for example, a Liquid Crystal Display (LCD) display, a Light Emitting Diode (LED) display, an Organic Light-Emitting Diode (OLED) display, a MicroElectroMechanical Systems (MEMS) display, or an electronic paper display. In an example, the display device 102 may be configured as a part of the data capture device 101 or as a separate device. The display device 102 may display, for example, a variety of contents (e.g., text, image, video, icons, symbols, etc.) to the individual. For example, the display device 102 may be configured to output one or more of the first user interface, the scanning device interface, the second user interface, and/or the third user interface output by the input/output interface 160. For example, the data capture device 101 may be configured to send the interfaces to the display device 102 for the display device 102 to output the interfaces to the individual instead of, or in addition to, the data capture device 101.

The electronic device 104 may comprise, for example, a laptop computer, a mobile phone, a smart phone, a tablet computer, a wearable device, a smartwatch, a haptic device, a desktop computer, a smart television, and the like. As an example, the electronic device 104 may be configured to output one or more of the first user interface, the scanning device interface, and/or the second user interface output by the input/output interface 160. For example, the data capture device 101 may be configured to send the interfaces to the electronic device 104 for the electronic device 104 to output to the interfaces to the individual instead of, or in addition to, the data capture device 101.

In an example, the electronic device 104 may comprise an image sensor, a camera device, a smart camera, an infra-red sensor, a depth/motion-capture sensor (e.g., RGB-D camera), a LiDAR sensor, and the like. For example, the electronic device 104 may be configured to capture the scans of the extremities (e.g., feet, hands, arms, legs, etc.), based on input received from the data capture device 101, and send the captured scans to the data capture device 101 for further processing. In an example, the electronic device 104 may be configured to provide the feedback to the individual during the scanning process. In an example, the electronic device 104 may send the completed scans to the data capture device 101, wherein the data capture device 101 may perform the process of determining whether the scans satisfy the quality threshold in order to determine whether any of the scans need to be retaken.

The server 106 may include a group of one or more servers. For example, all or some of the operations executed by the data capture device 101 may be executed in a different one or a plurality of electronic devices (e.g., the display device 102, the electronic device 104, and/or the server 106). In an example, if the data capture device 101 needs to perform a certain function or service either automatically or based on a request, the data capture device 101 may request at least some parts of functions related thereto alternatively or additionally to a different electronic device (e.g., the display device 102, the electronic device 104 and/or the server 106) instead of executing the function or the service autonomously. The different electronic devices (e.g., the display device 102, the electronic device 104, or the server 106) may execute the requested function or additional function, and may deliver a result thereof to the data capture device 101. The data capture device 101 may provide the requested function or service either directly or by additionally processing the received result. For example, a cloud computing, distributed computing, or client-server computing technique may be used.

In an example, the server 106 may include one or more databases. For example, the databases may be used to store a plurality of user profiles associated with a plurality of individuals. Scans associated with each individual may be stored in each individual's user profile. In an example, each individual may store one or more specific shoes (e.g., including shoe sizes and dimensions, shoe brands, shoe types, etc.) in each individual's user profile. In an example, each individual may store one or more specific modular footwear system designs in each individual's user profile. As an example, the individual may obtain pairs of shoe footbeds that are customized to the individual's feet, specific shoes, and/or specific modular footwear systems stored in the individual's user profile based on one or more scans of the individual's feet stored in the individual's user profile. In an example, each individual's user profile may further include additional information associated with the individual that may be used for creating/producing the footbeds of the individual. For example, the additional information may comprise one or more of a height, a weight, a desired length of the pair of footbeds to be produced, a desired upper material, or an identifier of the pair of footbeds to be produced. In an example, each individual's user profile may further include information associated with one or more shoe, or modular footwear system, designs based on the generated footbeds/scans associated with the individual's feet and based on the additional information. In an example, a group (e.g., school, business, organization, etc.) may create a group profile associated with individuals of the group. For example, a school may create a group profile of individuals of different sports teams, organizations, etc. The group may store one or more scans associated with each individual of the group within the group profile in addition to one or more specific shoes, or modular footwear systems, (e.g., including shoe sizes and dimensions) associated with the group and/or individuals of the group. As an example, the group may obtain pairs of shoe footbeds that are customized for each individual's feet and/or for specific shoes, or modular footwear systems, stored in the group's profile associated with each individual based on the one or more scans of each individual's feet stored in the group's profile. In an example, the group's profile may include additional information (e.g., height, weight, desired length of the pair of footbeds to be produced, desired upper material, identifier of the pair of footbeds to be produced, etc.) associated with each individual of the group that may be used for creating/producing the footbeds of the individuals of the group.

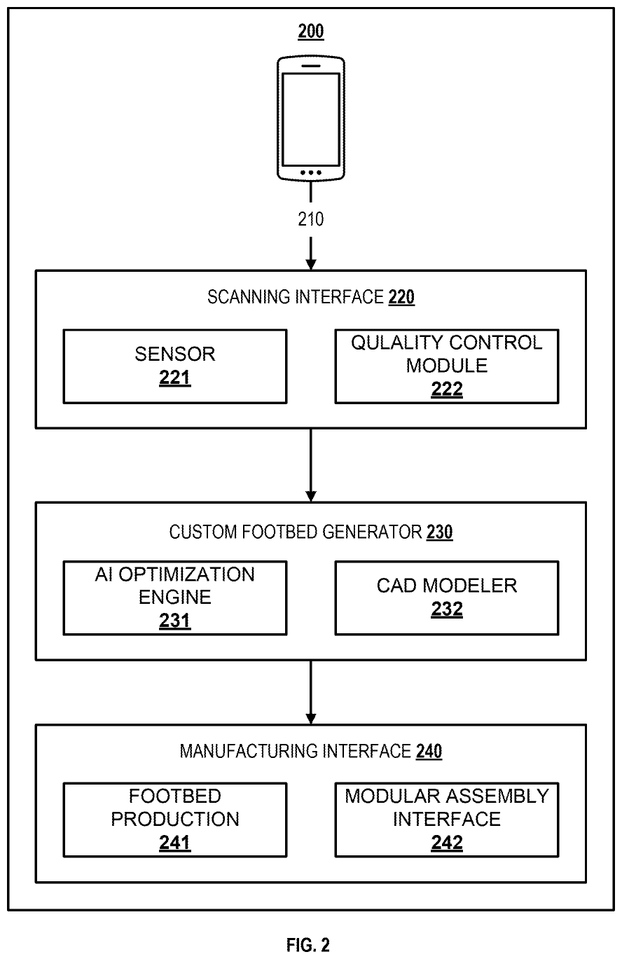

FIG. 2 shows an example system 200 for generating customized footbeds. The system 200 may comprise an integrated architecture that coordinates one or more system components via digital communication networks and standardized data interfaces. For example, the one or more system components of the system 200 may comprise a scanning interface 220, a custom footbed generator 230, and a manufacturing interface 240. As an example, the system 200 may enable comprehensive footwear customization (e.g., customized footbeds, shoes, and/or modular footwear systems) operations from initial user interaction through final product manufacturing and assembly. For example, the system architecture may incorporate modular design principles that allow one or more footwear components (e.g., footbed components, upper components, outsole components, etc.) to be upgraded, replaced, or reconfigured without disrupting overall system functionality. In an example, the system 200 may support multiple concurrent processing operations that enable simultaneous handling of numerous user requests while maintaining data integrity and processing accuracy across all system components. In an example, the system 200 may incorporate redundancy mechanisms, error recovery procedures, and quality assurance protocols that ensure reliable operation under diverse operating conditions and user demand scenarios.

A user interface 210 may be implemented (e.g., via the data capture device 101, the electronic device 104, etc.) to output (e.g., display) intuitive control mechanisms, visual feedback systems, and instructional content that guide users through a foot scanning and footwear product (e.g., footbed, shoe, modular footwear system, etc.) customization processes. For example, the user interface 210 may include an interface for delivering an instruction or data input from a user of the system 200 and an interface for outputting one or more user interfaces to the user. For example, the user interface 210 may comprise a display, such as a touch screen display, and/or one or more physical input interfaces (e.g., keyboard, mouse, etc.) configured to receive user inputs. As an example, the user interface 210 may be configured to accommodate user preferences through adaptive interface configurations that adjust complexity and guidance based on the user preferences and/or system settings. For example, the user interface 210 may incorporate touch controls, voice commands, gesture recognition, and/or other input modalities that enable flexible user interaction while maintaining ease of use and accessibility across a plurality of different users and user preferences. The user interface 210 may output real-time feedback, progress indicators, and quality assessment information associated with system status and processing outcomes throughout the customization workflow. For example, the user interface 210 may receive user input to initiate a scanning process, and thus, activating the scanning interface 220 for scanning a user's feet.

The scanning module 220 may comprise a sensor 221 and a quality control module 222. The sensor 221 may comprise an image sensor, a camera, a depth/motion capture sensor (e.g., RGB-D camera), or any device configured to take/capture scans (e.g., three-dimensional scans) of a user's feet. The scanning module 220 may coordinate multiple scanning technologies and quality assessment procedures to ensure comprehensive foot geometry data collection that meets the specifications for subsequent processing and manufacturing operations of footbeds, shoes, and/or modular footwear systems. For example, the scans may be captured by the sensor 221 based on one or more of an infrared dot blotter, a gyroscope, a light detection and ranging (LiDAR) sensor, etc. For example, the scanning process may be initiated based on user input via the user interface 210 or based on the user placing a foot in front of the sensor 221, wherein the sensor 221 may automatically initiate the scanning process after detecting that the foot is in a correct position in front of the sensor 221. The sensor 221 may scan the user's foot as the sensor 221 is moved around the foot to capture each area of the foot. For example, the sensor 221 may utilize multiple sensing technologies, such as structured light projection, time-of-flight measurement, or photogrammetry techniques, in order to capture comprehensive surface geometry data from multiple viewing angles and positions. In an example, the sensor 221 may incorporate automated positioning systems, lighting controls, or environmental compensation mechanisms that optimize data capture quality under diverse operating conditions (e.g., different background lighting, etc.). The sensor 221 may generate point cloud data, mesh representations, or parametric surface models that provide detailed geometric descriptions of individual foot characteristics including arch height, width variations, and surface contours. The scanning system may accommodate different foot positions including weight-bearing and non-weight-bearing configurations that capture both static geometry and dynamic characteristics relevant to footwear design and manufacturing. For example, the scanning module 220 may generate comprehensive datasets that include surface topology, dimensional measurements, and biomechanical positioning information that provides complete input data for generating customized footbeds, customized shoes, and/or customized modular footwear systems.

The quality control module 222 may be configured to provide an automated assessment of scan data quality, completeness, and accuracy before the scan data proceeds to subsequent processing operations. For example, the quality control module 222 may implement one or more machine learning models, statistical analysis procedures, or geometric validation techniques that evaluate scan data against established quality criteria and manufacturing requirements. For example, the quality control module 222 may identify data deficiencies, scanning errors, or quality issues that require additional data collection or scan repetition to ensure successful processing outcomes. For example, the quality control module 222 may implement automated error detection, data completeness verification, and dimensional accuracy validation that ensure the collected scan data meets the specifications for reliable custom footbed generation and manufacturing operations. For example, the machine learning models may include a segmentation model and/or a classification model. The segmentation model may be configured to process the point cloud data in order to generate a segmented point cloud, for each scan, based on removing points of the point cloud that do not make up a user's foot captured by a plurality of scans generated by the sensor 221. The classification model may be configured to process the segmented point cloud in order to determine whether each scan satisfies a quality threshold (e.g., edge clarity threshold, proper positioning threshold, etc.). The scans that do not satisfy the quality threshold may then be retaken until the scans satisfy the quality threshold. The quality control module 222 may provide real-time feedback through the user interface 210 that may indicate scan quality status, completion requirements, or corrective actions needed to achieve acceptable data quality. For example, as the sensor 221 receives the scans, the quality control module 222 may provide feedback (e.g., haptic feedback, audio feedback, visual feedback, etc.) via the user interface 210. The feedback may indicate that the sensor 221 is continuing to collect data, real-time course-correction indicators as the user scans the extremity, the scanning process terminated based on an error during the scanning process, and/or the scanning process has completed. In an example, an object mapping program may operate in unison with the quality control module 222 during the recording process to identify when a threshold amount of data across relevant regions/portions of the user's foot has been collected.

The custom footbed generator 230 may be configured to receive validated scan data (e.g., scan data that satisfied the quality threshold) and transform the geometric information of the scan data into detailed custom footbed specifications (e.g., footbed design). For example, the custom footbed generator 230 may implement one or more processing algorithms that analyze individual foot characteristics and generate personalized support structures tailored to specific biomechanical requirements and comfort preferences. The custom footbed generator 230 may utilize algorithmic surface optimization in addition to 3D scanning for generating the custom footbed geometry through computational procedures that enhance the scan data with biomechanical modeling, pressure distribution analysis, and structural optimization techniques. In an example, the custom footbed generator 230 may incorporate user preference data, activity requirements, or medical considerations that further refine the footbed design. As an example, the custom footbed generator 230 may produce detailed manufacturing specifications including material selections, surface treatments, and dimensional tolerances (e.g., the detailed custom footbed specifications) that define complete production requirements for generating a customized footbed component. For example, the custom footbed generator 230 may comprise an artificial intelligence (AI) optimization engine 231 and a computer-aided design (CAD) modeler 232.

The AI optimization engine 231 may be configured to provide advanced computational capabilities that enhance footbed design through machine learning algorithms, biomechanical modeling, and performance optimization procedures. For example, the AI optimization engine 231 may analyze large datasets of foot geometry, user feedback, and performance characteristics to identify design patterns and optimization opportunities that improve comfort, support, and durability characteristics of custom footbeds. The AI optimization engine 231 may incorporate neural networks, genetic algorithms, or other artificial intelligence techniques that continuously refine footbed design parameters based on accumulated user data and manufacturing feedback. The AI optimization engine 231 may perform predictive modeling that anticipates user comfort preferences, wear patterns, or performance requirements based on foot geometry characteristics and user profile information. The AI optimization engine 231 may implement manufacturing constraints, material properties, and cost considerations that ensure the generated footbed designs are compatible with available production capabilities while maximizing performance characteristics.

The CAD modeler 232 may generate footbed models based on the footbed designs. For example, the CAD modeler 232 may be configured to provide computer-aided design capabilities that transform the generated footbed designs into detailed manufacturing models and production documentation (e.g., custom footbed specifications). The CAD modeler 232 may generate three-dimensional solid models, surface representations, or parametric footbed designs that define the complete geometric characteristics of customized footbeds with manufacturing precision and accuracy. The CAD modeler 232 may incorporate design rule checking, manufacturability analysis, or tolerance verification procedures that ensure the generated footbed models are compatible with available manufacturing processes and equipment capabilities. The CAD modeler 232 may generate the footbed models according to different output formats such as machine code, tooling specifications, and/or quality inspection programs that support diverse manufacturing technologies and production workflows. As an example, the custom footbed generator 230 may incorporate version control, design history tracking, or change management capabilities that maintain comprehensive documentation of design evolution and manufacturing specifications throughout the production process.

The manufacturing interface 240 may receive the footbed models from the custom footbed generator 230 in order to coordinate multiple manufacturing technologies, production scheduling systems, and quality control procedures that enable efficient production of customized footbeds according to the generated footbed models. The manufacturing interface 240 may incorporate production planning algorithms, resource allocation procedures, or workflow optimization techniques that maximize manufacturing efficiency while maintaining quality consistency across multiple production orders. The manufacturing interface 240 may support integration with existing manufacturing systems, enterprise resource planning platforms, or supply chain management networks that coordinate custom footbed production within broader manufacturing operations. In an example, the manufacturing interface 240 may generate production reports, quality documentation, or traceability records that provide comprehensive documentation of manufacturing processes and product characteristics for quality assurance and customer service purposes. The manufacturing interface 240 may comprise a footbed production interface 241 and a modular assembly interface 242.

The footbed production interface 241 may incorporate specialized manufacturing equipment, material handling systems, or quality control procedures that produce customized footbeds according to the footbed models generated by the custom footbed generator 230. The production component may utilize additive manufacturing technologies, subtractive machining processes, or hybrid production techniques that create custom footbeds with the dimensional accuracy and material properties specified in the design documentation (e.g., footbed model). The footbed production interface 241 may incorporate real-time quality monitoring, dimensional verification, or material property testing that ensures produced footbeds meet design specifications and performance requirements before proceeding to assembly operations.

The modular assembly interface 242 may coordinate the integration of custom footbeds with modular upper and outsole components to create complete customized footwear products (e.g., modular footwear systems) through automated or semi-automated assembly procedures. The assembly component may incorporate specialized tooling, positioning systems, or bonding equipment that ensure proper component alignment and attachment during the assembly process. The modular assembly interface 242 may support multiple assembly methodologies including adhesive bonding, mechanical fastening, or hybrid attachment systems that provide durable connections between the customized footbeds and the modular components (e.g., upper component, outsole component, etc.). The modular assembly interface 242 may implement quality inspection, functional testing, or performance verification operations that ensure completed footwear products (e.g., modular footwear systems) meet design specifications and performance requirements before packaging and distribution operations.

As an example, the modular footwear system (e.g., footwear product) comprising one or more footwear components may be produced based on the customized footbeds. For example, the one or more footwear components of the modular footwear system may comprise the footbed produced based on the plurality of scans, an upper component, and an outsole component. The footbed may further comprise one or more attachment interfaces along a perimeter of the footbed. The one or more attachment interfaces may comprise one or more dual-axis locking tabs configured to provide fore-aft and lateral stability between the footbed and the upper component, one or more magnetic aligners configured to align the footbed with the upper component, one or more adaptive fit anchors (e.g., elastic loops) configured to allow an individual wearing the modular footwear system to tension the upper component, and/or one or more anti-rotation features configured to prevent slippage under load (e.g., a person standing up). The one or more magnetic aligners may comprise one or more RFID-based placement guides configured to provide real-time assembly guidance and component verification. The one or more anti-rotation features may comprise one or more key-and-slot designs. The upper component may be configured to couple to a top portion of the footbed via the one or more attachment interfaces. In addition, the outsole component may be configured to couple to a bottom portion of the footbed via the one or more attachment interfaces. In an example, the footbed may further comprise one or more perimeter dovetails (e.g., magnetic alignment wells) configured to align the footbeds with the upper component and outsole component. In an example, the footbed, the upper component, and/or the outsole component may comprise one or more embedded near field communication (NFC) tags and/or QR coding. For example, the footbed, the upper component, and/or the outsole component may may be matched for their intended shell variants. In an example, the QR code may be used to link a modular footwear system and/or one of its footwear components (e.g., the footbed, the upper component, and/or the outsole component) to the user (e.g., user profile) and/or order metadata. As an example, the footbed, the upper component, and/or the outsole component may be matched to each other based on the one or more embedded NFC tags and/or the QR coding. In an example, the embedded NFC tags may be utilized to implement digital identification and verification proceeds to confirm matching of the footwear components and prevent assembly errors and ensure component compatibility. For example, the embedded NFC tags may store component identification data, manufacturing specifications, or compatibility information that enables automated verification of accurate component pairing during assembly operations. The NFC tags may communicate with assembly equipment, quality control systems, or mobile applications that provide real-time feedback regarding component matching and assembly correctness. As such, the NFC tags may enable traceability throughout the manufacturing and assembly process while providing quality assurance mechanisms that prevent incorrect component combinations or assembly errors that could compromise product performance or user satisfaction. In an example, the QR codes may comprise machine-readable codes that provide comprehensive product identification and traceability capabilities. For example, the QR codes may store customer information, footbed design specifications, manufacturing data, or assembly instructions that enable automated processing throughout the production and fulfillment workflow. The QR codes may be updated dynamically to reflect changes in order status, manufacturing progress, or quality control results that provide real-time tracking capabilities for both manufacturers and customers. The QR codes may be integrated with inventory management systems, shipping networks, or customer service platforms that coordinate product fulfillment and support operations based on encoded product and customer information.

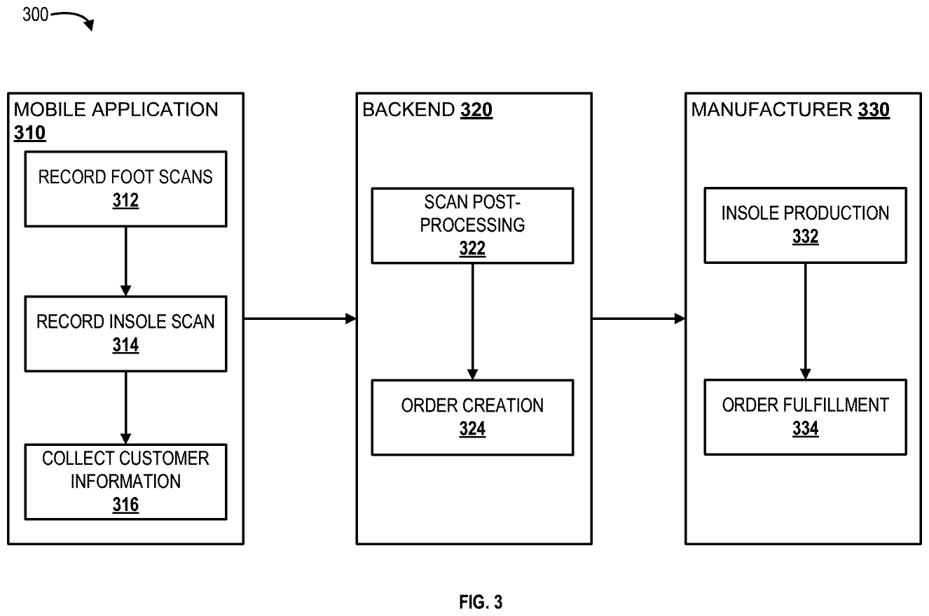

FIG. 3 shows an example system 300 for producing a pair of footbeds. The system 300 may comprise a mobile application 310, a backend 320, and a manufacturer 330. The mobile application may be implemented by a user device (e.g., data capture device 101 and/or electronic device 104). As an example, the mobile application may comprise the scan processing program 157 and/or the machine learning programs/models 159. At 312, the mobile application 310 may be configured to process and record scans of an individual's foot. The mobile application 310 may determine whether each scan of the completed scans satisfy a quality threshold. For example, the application may determine that a first one or more scans of the completed scans satisfy the quality threshold and that a second one or more scans of the completed scans do not satisfy the quality threshold. In an example, the mobile application 310 may process the scans via one or more machine learning models (e.g., the machine learning programs/models 159) such as a segmentation model and/or a classification model. The segmentation model may be configured to process the completed scans to determine points of a point cloud that make up the foot, in each scan, and remove the points of the point cloud that do not make up the foot. For example, the point cloud may be generated based on applying the segmentation model to the plurality of scans. The segmentation model may then generate a segmented point cloud, for each scan, based on removing the points from the point cloud for each scan that do not make up the foot. The segmented point cloud of each scan may then be sent to the classification model, wherein the classification model may determine whether each scan satisfies the quality threshold (e.g., edge clarity threshold, proper positioning threshold, etc.). The scans that do not satisfy the quality threshold may then be retaken until the scans satisfy the quality threshold. In an example, the scans that do not satisfy the quality threshold may be stored for further labeling to be used as training data for the one or more machine learning programs/models.

In an example, a self-augmenting fit profile based on a computer vision wear assessment may be implemented by scanning a pair of footbeds of the individual that have been worn by the individual for a period of time (e.g., days, weeks, months, years, etc.). The fit profile may be stored in the individual's profile to be used with the one or more scans of an individual's for further enhancing the design of the individual's footbeds. For example, footbeds may be produced/created based on the one or more scans and the fit profile of the individual.

At 314, the mobile application 310 may use the completed scans, including the retaken scans, that satisfy the quality threshold may to generate footbed designs for the individual. In an example, the mobile application 310 may also use shoe information (e.g., data) associated with one or more pairs of shoes stored in the individual's user profile to generate the footbed designs that are customized for each of the one or more pairs of shoes. For example, the individual may create a user profile for storing the scans for creating/producing footbeds for the individual and the shoe information. The footbed designs may be stored on the user device or in a database of a server (e.g., server 106) in the individual's user profile. After the footbed designs are created, the mobile application 310 may collect customer information of the individual. For example, the mobile application 310 may collect one or more of a height of the individual, a weight of the individual, a desired length of the pair of footbeds to be produced, a desired upper material, an identifier of the pair of footbeds to be produced, etc.

The mobile application 310 may further send the footbed designs to a backend 320 for further processing. As an example, the backend 320 may be implemented by a server (e.g., server 106). The backend 320 may perform footbed design post processing at 322. In an example, part or all of the post processing may be performed by a backend or server associated with the manufacturer 330. In an example, the backend 320 may generate one or more shoe, or modular footwear system, designs based on the generated footbed design and/or based on the scans of the individual's feet. In one example, one or more types of shoe designs (e.g., sneakers, dress shoes, high heel shoes, running shoes, soccer shoes, football shoes, etc.) may be generated based on the footbeds associated with the scans of the individual's feet. In another example, one or more modular footwear system designs may be generated that comprise one or more footwear components (e.g., a customized footbed, an upper component, and/or an outsole component). Based on the footbed design post processing 322, the backend 320 may create orders for one or more pairs of customized footbeds for the individual at 324. In an example, based on the one or more of the generated shoe, or modular footwear system, designs, the backend 320 may create orders for one or more pairs of shoes (e.g., customized shoes), or modular footwear systems, for the individual.

The backend 320 may send the orders of the one or more pairs of footbeds and/or the orders for the one or more pairs of shoes, or modular footwear systems, to the manufacturer 330. At 332, the manufacturer 330 may produce the one or more pairs of footbeds based on the footbed designs. In an example, the manufacturer 330 may produce the one or more pairs of shoes, or modular footwear systems, based on the shoe, or modular footwear system, designs. At 334, the manufacture 330 may fulfill the order by sending the one or more pairs of footbeds and/or the one or more pairs of shoes, or modular footwear systems, to the individual. In an example, the mobile application 310 may provide an option to send the pair of footbeds, the footbed designs, and/or the scans to a store (e.g., company, organization, etc.). The store may establish a store-specific user profile, wherein the store may provide custom footbeds for the user based on the user profile, such as based on user preferences for certain shoe brands, types, etc. In an example, the backend 320 may be configured to integrate functions with one or more third-party applications (e.g., branded e-commerce applications associated with one or more retail distributors, stores, etc.).

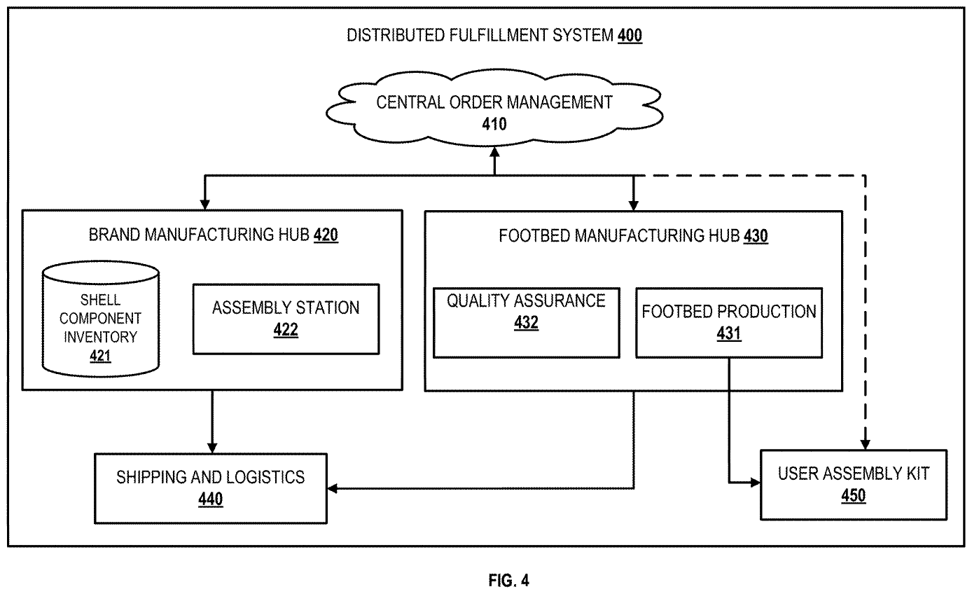

FIG. 4 shows a distributed fulfillment system 400 for generating customized footbeds. The distributed fulfillment system 400 may comprise a networked architecture that manages and fulfills custom product orders (e.g., for footbeds, shoes, and/or modular footwear systems) across multiple manufacturing locations through coordinated communication and workflow management systems. The distributed fulfillment system 400 may enable parallel processing of different product components (e.g., footbeds, and/or footwear components) at specialized facilities while maintaining synchronization of assembly and delivery operations for complete custom footwear products (e.g., footbeds and/or modular footwear systems). The system architecture may incorporate redundancy mechanisms, load balancing capabilities, and quality assurance protocols that ensure reliable operation under varying demand conditions and manufacturing capacity constraints. The distributed fulfillment system 400 may support multiple fulfillment models including centralized assembly, distributed assembly, and user-directed assembly operations that accommodate different customer preferences and business requirements. The distributed fulfillment system 400 may generate comprehensive tracking data, performance metrics, and quality documentation that enable continuous optimization of fulfillment processes and customer satisfaction outcomes. The distributed fulfillment system 400 may comprise a central order management component 410, a brand manufacturing hub 420, a footbed manufacturing hub 430, and a shipping and logistics component 440.

The central order management component 410 may comprise a cloud-based system that coordinates overall order processing operations and maintains centralized control over the distributed manufacturing and fulfillment network. The central order management component 410 may receive customer orders, process customization requirements, and generate manufacturing specifications that are distributed to appropriate production facilities based on component requirements and manufacturing capabilities. The central order management component 410 may incorporate order routing algorithms, capacity planning procedures, and scheduling optimization techniques that maximize production efficiency while minimizing delivery timelines across the distributed network. The central order management component 410 may maintain real-time communication with all network components through secure data transmission protocols that preserve order integrity and customer privacy throughout the fulfillment process. The central order management component 410 may generate production schedules, quality requirements, and delivery coordination instructions that ensure synchronized operations across multiple manufacturing and assembly locations.

The central order management component 410 may be configured to maintain bidirectional communication with the brand manufacturing hub 420 and the footbed manufacturing hub 430 to enable real-time coordination of production activities and resource allocation decisions. The bidirectional communication may facilitate dynamic adjustment of production schedules, quality requirements, or delivery timelines based on changing demand patterns or manufacturing capacity variations. The central order management component 410 may be configured to implement a distributed protocol that governs routing of components (e.g., footbed components, upper components, outsole components, etc.) to appropriate assembly nodes based on component specifications, manufacturing capabilities, and delivery requirements. The distributed protocol may incorporate decision algorithms that evaluate multiple factors including production capacity, geographic proximity, quality capabilities, and cost considerations to optimize routing decisions for individual orders. The protocol may enable dynamic rerouting of orders based on real-time manufacturing status, quality issues, or capacity constraints that ensure consistent fulfillment performance across the distributed network.

The brand manufacturing hub 420 may be configured to produce, and/or assemble, branded footwear components (e.g., upper components and/or outsole components with branded footwear elements) while integrating customized footbeds into established manufacturing workflows. The brand manufacturing hub 420 may accommodate existing footwear manufacturing processes while incorporating specialized handling and assembly procedures that may be utilized for customized footbed integration with the upper component and the outsole component. The brand manufacturing hub 420 may maintain inventory management systems, production scheduling capabilities, and quality control procedures that ensure consistent integration of footwear components with branded footwear elements. For example, the brand manufacturing hub 420 may support multiple footwear brands, product lines, or manufacturing specifications through flexible production capabilities and standardized interface protocols. The brand manufacturing hub 420 may receive footbed models (e.g., based on footbed designs that are generated based on scans of users'feet), production schedules, and quality requirements, via the central order management component 410, enabling seamless integration of customized footbeds with branded footwear components into branded footwear products (e.g., branded footwear systems). The brand manufacturing hub 420 may comprise a shell component inventory database 421 and an assembly station 422.

The shell component inventory database 421 may store data indicative of a stock list of pre-manufactured upper components and outsole components for integration with customized footbeds during assembly operations. The shell component inventory database 421 may include automated storage and retrieval systems, inventory tracking capabilities, and quality preservation procedures that ensure component availability and condition for assembly operations. The shell component inventory database 421 may store data indicative of one or more component variations (e.g., footwear component variations) including different sizes, styles, materials, or performance characteristics according to different customer requirements and product specifications. The shell component inventory database 421 may incorporate forecasting algorithms, demand planning procedures, and supplier coordination systems that optimize inventory levels while minimizing storage costs and component obsolescence. As an example, inventory management associated with the shell component inventory database 421 may support just-in-time delivery of components to assembly operations while maintaining buffer stocks that accommodate demand variations and supply chain disruptions.

The assembly station 422 may be configured to provide specialized equipment and procedures for combining the customized footbeds with the footwear components stored in the shell component inventory database 421. The assembly station 422 may incorporate positioning fixtures, bonding equipment, and quality verification systems that ensure proper alignment and attachment of the customized footbeds with the branded footwear components. The assembly station 422 may utilize alignment fixtures and adhesives for assembling components around customized footbeds through controlled processes that maintain dimensional accuracy and bond strength consistency. The assembly station 422 may accommodate multiple assembly methodologies including adhesive bonding, mechanical fastening, or hybrid attachment systems that provide durable connections between the customized footbeds with the branded footwear components. The assembly station 422 may incorporate automated handling systems, process monitoring capabilities, and quality inspection procedures that optimize assembly efficiency while maintaining consistent product quality across production volumes.

The footbed manufacturing hub 430 may comprise a specialized facility component that is configured to implement footbed production and quality assurance operations. The footbed manufacturing hub 430 may incorporate one or more manufacturing technologies, quality control systems, and customization capabilities that enable high-precision production of customized footbed components. For example, the footbed manufacturing hub 430 may receive the custom footbed models from the central order management component 410 and coordinate production scheduling with delivery requirements for integration at various assembly locations. The footbed manufacturing hub 430 may be configured to implement one or more manufacturing technologies including additive manufacturing, subtractive machining, or hybrid production processes that accommodate different footbed materials and design specifications. As an example, the footbed manufacturing hub 430 may maintain comprehensive quality documentation, traceability records, and performance data that enable continuous improvement of footbed production processes and customer satisfaction outcomes. The footbed manufacturing hub 430 may comprise a footbed production component 431 and a quality assurance component 432.

The footbed production component 431 may be configured to incorporate specialized manufacturing equipment, material handling systems, and process control procedures that enable high-precision production of the customized footbeds with consistent quality and performance characteristics. The footbed production component 431 may utilize algorithmic surface optimization techniques, computer-aided manufacturing systems, and automated quality monitoring procedures that transform the footbed models (e.g., digital footbed specifications) into physical components with manufacturing precision. The footbed production component 431 may be configured to accommodate one or more material options, surface treatments, and structural configurations that provide diverse customization capabilities while maintaining production efficiency and cost effectiveness. The footbed production component 431 may generate production documentation, quality records, and traceability data that enable comprehensive tracking of the customized footbed manufacturing processes and performance characteristics.

The quality assurance component 432 may be configured to implement inspection, testing, and verification procedures of the customized footbeds that ensure the customized footbeds meet design specifications and performance requirements before distribution to assembly locations. The quality assurance component 432 may implement dimensional verification, material property testing, and functional performance evaluation procedures that validate footbed characteristics against established quality criteria. The quality assurance component 432 may incorporate automated inspection equipment, statistical process control systems, and documentation procedures that maintain comprehensive quality records for each custom footbed produced. The quality assurance component 432 may receive production and manufacturing information from the central order management 410 in order to output real-time quality status information and resolve any quality issues that may affect delivery schedules or customer satisfaction. The quality assurance component 432 may be configured with one or more quality databases, performance tracking systems, and continuous improvement procedures that may be utilized to optimize footbed production quality and consistency over time.

The shipping and logistics component 440 may be configured with transportation and delivery coordination systems that manage product movement throughout the distributed fulfillment system 400 network. The shipping and logistics component 440 may coordinate delivery of the customized footbeds from the footbed manufacturing hub 430 (e.g., from the footbed production component 431) to different assembly locations, distribution of completed products from the brand manufacturing hub 420 to customers, and delivery of user assembly kits 450 to end users. The shipping and logistics component 440 may configured to implement route optimization, delivery scheduling, and tracking capabilities that minimize transportation costs while meeting customer delivery requirements. The shipping and logistics component 440 may support multiple delivery options including expedited shipping, standard delivery, or consolidated shipments that accommodate different customer preferences and cost considerations. The shipping and logistics component 440 may be configured to maintain comprehensive tracking data, delivery confirmation procedures, and customer communication systems that provide shipping and logistics data indicative of product movement and delivery status information associated with the manufacturing and delivery of the customized footbeds.

In an example, user assembly kit(s) 450 comprising the completed modular component systems (e.g., the completed footbeds, upper components, and outsole components) may be provided to end users for self-assembly of the modular footwear systems. For example, the user assembly kit(s) 450 may include provided instruction and tooling for user assembly of the footwear components, including the customized footbeds, through comprehensive assembly guides, specialized tools, and quality verification procedures that enable successful footwear component integration by the end users. The user assembly kit(s) 450 may contain detailed assembly instructions, video tutorials, or interactive guidance systems that communicate proper assembly procedures and quality checkpoints to users with varying technical experience levels. The user assembly kit(s) 450 may include specialized tools, alignment fixtures, or assembly aids that facilitate proper component positioning and attachment during user assembly operations. The user assembly kit(s) 450 may incorporate quality verification procedures, troubleshooting guides, or customer support contact information that ensure successful assembly outcomes and customer satisfaction.

In an example, the distributed fulfillment system 400 may support the integration of midsole layers offering tunable stack heights or rebound properties as interchangeable components that can be manufactured and distributed through the same network infrastructure used for the customized footbeds and footwear components of the modular footwear systems. The midsole layers may be produced at specialized facilities within the distributed fulfillment system 400 and distributed to assembly locations based on customer specifications and performance requirements. The tunable characteristics may enable customers to modify footwear performance characteristics including cushioning levels, energy return properties, or stack height configurations through component substitution or layering approaches. The interchangeable midsole layers may incorporate standardized interface features that ensure compatibility with the customized footbeds and footwear components while providing performance customization capabilities.

In an example, the distributed fulfillment system 400 may support third-party component systems wherein brands or designers may produce compatible footwear shells, or components, for the customized footbeds via standardized interface specifications and quality certification procedures. The third-party system may enable expanded component availability, design diversity, and market competition while maintaining compatibility with the customized footbeds, including modular footwear systems, and assembly procedures. The third-party system may be configured to implement interface standards, quality requirements, and certification processes that ensure third-party components meet performance and compatibility specifications for integration with the customized footbeds. The central order management component 410 may coordinate third-party component availability, quality verification, and delivery scheduling to ensure seamless integration of external components into the distributed fulfillment network.

The integration of the distributed fulfillment system 400 through a comprehensive network architecture that coordinates custom product (e.g., footbed and/or modular footwear systems) manufacturing and delivery operations across multiple specialized facilities and assembly locations enables scalable processing of personalized/customized footwear orders while maintaining quality consistency and production efficiency across diverse geographic regions and manufacturing capabilities. The distributed approach accommodates different aspects, or phases, of manufacturing including brand-integrated manufacturing, specialized component production, and user-directed assembly operations that provide flexibility in fulfillment methodologies while optimizing cost efficiency and delivery timelines.

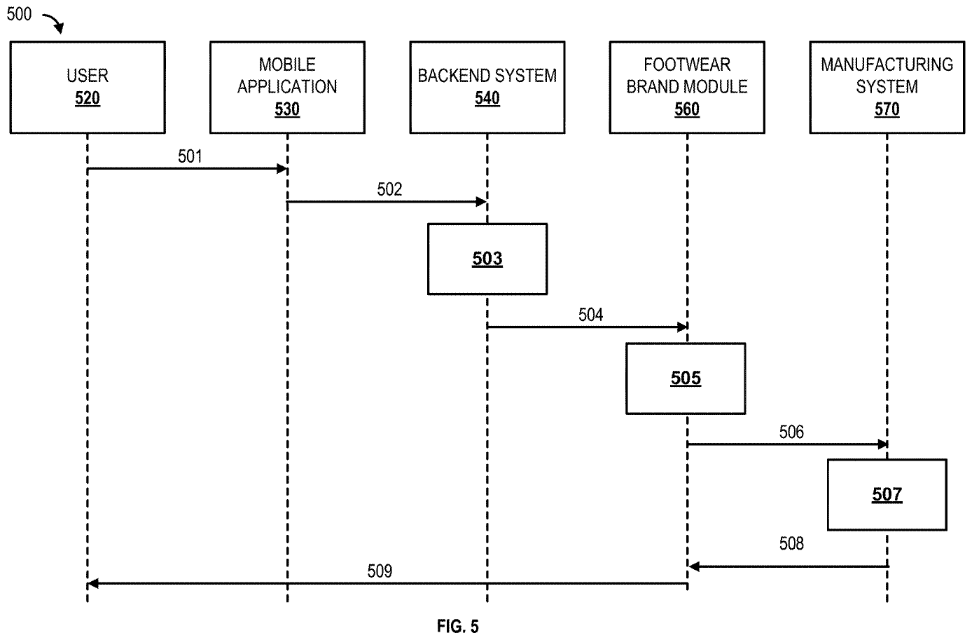

FIG. 5 shows an example process 500 for generating customized footbeds. The process 500 may be implemented by a user device 520 (a data capture device 101, electronic device 104, combinations thereof, etc.), a mobile application 530, a backend system 540, a footwear brand module 560, and a manufacturing system 570. At 501, the mobile application 530 may receive scan data (e.g., a plurality of scans) from the user device 520. For example, a user of the user device 520 may initiate a scanning process for capturing a plurality of scans of the user's foot. As an example, the mobile application 530 may process each scan of the scan data to determine that data associated with a first one or more scans of the plurality of scans satisfies a quality threshold and that data associated with a second one or more scans of the plurality of scans does not satisfy the quality threshold. For example, the mobile application 530 may process the plurality of scans via a segmentation model and a classification model. The segmentation model may be configured to process the plurality of scans to determine points of a point cloud that make up the user's foot, in each scan, and remove points of the point cloud that do not make up the user's foot. The segmentation model may then generate a segmented point cloud, for each scan, based on removing the points of the point cloud that do not make up the user's foot. The segmented point cloud of each scan may then be sent to the classification model, wherein the classification model may determine whether each scan satisfies the quality threshold (e.g., edge clarity threshold, proper positioning threshold, etc.). The scans that do not satisfy the quality threshold may then be retaken until the scans satisfy the quality threshold. At 502, the mobile application 530 may provide the scan data to the backend system 540, wherein the backend system 540 may process the scan data. As an example, the mobile application 530 may provide scan data that includes that scans, including the retaken scans, that satisfy the quality threshold to the backend system 540.

At 503, the backend system 540 may generate a footbed design based on the scan data. In an example, the backend system 540 may convert the point clouds of the scans that satisfied the quality threshold to a CAD mesh (e.g., a mesh representation) of the user's foot. In an example, the backend system 540 may store the CAD mesh in a user profile associated with the user. For example, the user may create a user profile for storing the scans, or the CAD meshes, to be used for creating customized footbed designs for the user. The user profile may be stored in a database, such as a database of the backend system 540. As an example, the backend system 540 may generate the footbed design based on the CAD mesh of the user's foot. At 504, the backend system 540 may provide the footbed design to the footwear brand module 560.

At 505, the footwear brand module 560 may be configured to incorporate the footbed design into footbed manufacturing specifications. For example, a footbed model may be generated according to data indicative of one or more shoe characteristics. The data indicative of the one or more shoe characteristics may comprise one or more of data indicative of one or more scans of an interior of a shoe, data indicative of an interior shape of the shoe, data indicative of one or more scans of the footbed designed to fit in the shoe, data indicative of a shape of the footbed designed to fit in the shoe, data indicative of a shoe height, data indicative of a shoe width, or data indicative of a shoe material. As an example, the footbed model may be generated such that a footbed may be produced from the footbed model such that an outside edge of the footbed matches exactly to the perimeter of a shoe associated with the one or more shoe characteristics, or shoe lasts, in order to provide a perfect fit for the user according to the user's shoes. In an example, the footwear brand module 560 may generate the footbed model based on scans of a sock liner of the shoe. The footbed may be produced such that the outside edge of the footbed aligns to a perimeter of the sock liner (e.g., prefabricated footbed) of the shoe. At 506, the footwear brand module 560 may provide the footbed manufacturing specifications (e.g., the footbed model) to the manufacturing system 570.

At 507, the manufacturing system 570 may be configured to generate/produce a shoe, including a footbed, according to the footbed manufacturing specifications (e.g., the footbed model). For example, the manufacturing system 570 may be configured to generate/produce a modular footwear system according to the footbed manufacturing specifications (e.g., the footbed model). As an example, the modular footwear system may comprise one or more footwear components designed according to the footbed manufacturing specifications. The one or more footwear components may comprise the footbed produced based on the footbed model, an upper component, and an outsole component. In an example, the footbed may further comprise one or more attachment interfaces along a perimeter of the footbed. The one or more attachment interfaces may comprise one or more dual-axis locking tabs configured to provide fore-aft and lateral stability between the footbed and the upper component, one or more magnetic aligners configured to align the footbed with the upper component, one or more adaptive fit anchors (e.g., elastic loops) configured to allow an individual wearing the modular footwear system to tension the upper component, and/or one or more anti-rotation features configured to prevent slippage under load (e.g., a person standing up). The one or more magnetic aligners may comprise one or more RFID-based placement guides configured to provide real-time assembly guidance and component verification. The one or more anti-rotation features may comprise one or more key-and-slot designs. The upper component may be configured to couple to a top portion of the footbed via the one or more attachment interfaces. In addition, the outsole component may be configured to couple to a bottom portion of the footbed via the one or more attachment interfaces. In an example, the footbed may further comprise one or more perimeter dovetails (e.g., magnetic alignment wells) configured to align the footbeds with the upper component and outsole component. In an example, the footbed, the upper component, and/or the outsole component may comprise one or more embedded near field communication (NFC) tags and/or QR coding. For example, the footbed, the upper component, and/or the outsole component may may be matched for their intended shell variants. In an example, the QR coding may be used to link a modular footwear system and/or one of its footwear components (e.g., the footbed, the upper component, and/or the outsole component) to an individual (e.g., user profile) and/or order metadata. As an example, the footbed, the upper component, and/or the outsole component may be matched to each other based on the one or more embedded NFC tags and/or the QR coding.

As an example, the manufacturing system 570 may incorporate production planning algorithms, resource allocation procedures, or workflow optimization techniques that maximize manufacturing efficiency while maintaining quality consistency across multiple production orders. The manufacturing system 570 may support integration with existing manufacturing systems, enterprise resource planning platforms, or supply chain management networks that coordinate custom footbed production within broader manufacturing operations. In an example, the manufacturing system 570 may generate production reports, quality documentation, or traceability records that provide comprehensive documentation of manufacturing processes and product characteristics for quality assurance and customer service purposes.

At 508, the manufacturing system 570 may provide the footbed and/or the entire modular footwear system to the footwear brand module 560. At 509, the footwear brand module 560 may provide the footbed and/or the entire modular footwear system to the user of the user device 520. As an example, the modular footwear system may be provided to the user pre-assembled or as multiple components to be assembled by the user.

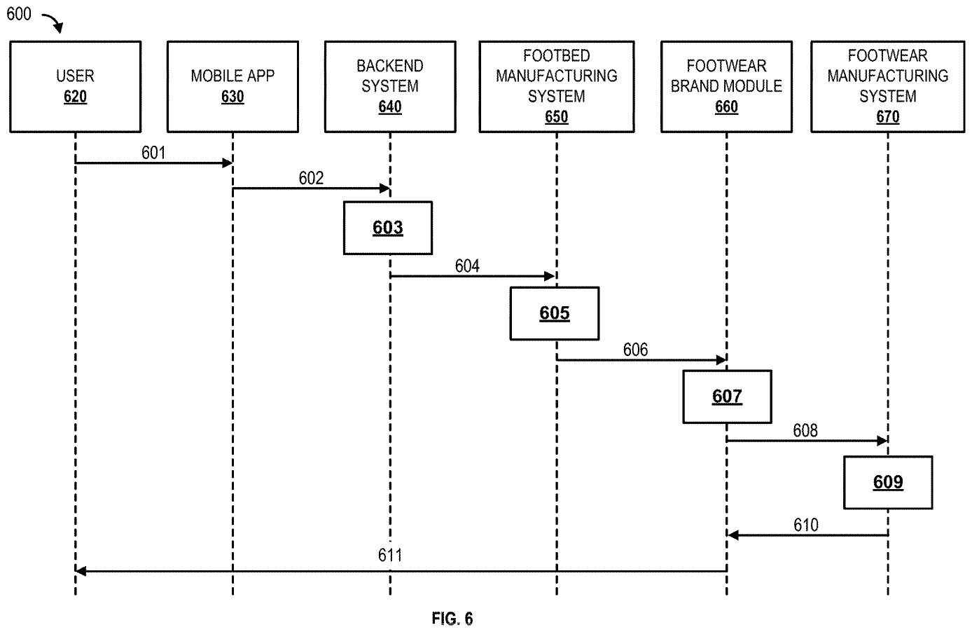

FIG. 6 shows an example process 600 for generating customized footbeds. The process 600 may be implemented by a user device 620 (a data capture device 101, electronic device 104, combinations thereof, etc.), a mobile application 630, a backend system 640, a footbed manufacturing system 650, a footwear brand module 660, and a manufacturing system 670. Steps 601-603 are similar to steps 501-503 in FIG. 5. At 604, the backend system 640 may provide the footbed design to the footbed manufacturing system 650.

At 605, the footbed manufacturing system 650 may be configured to produce a footbed according to the footbed design. For example, the footbed manufacturing system 650 may produce the footbed according to user feet characteristics captured by the scan data (e.g., the plurality of scans that satisfy the quality threshold) of the user's feet. In one example, the user may store specific shoes in the user profile. As an example, footbeds may be created/produced (e.g., customized) for each of the user's shoes stored in the individual's user profile. In another example, the footbed may be produced according to data indicative of one or more shoe characteristics. The data indicative of the one or more shoe characteristics may comprise one or more of data indicative of one or more scans of an interior of a shoe, data indicative of an interior shape of the shoe, data indicative of one or more scans of the footbed designed to fit in the shoe, data indicative of a shape of the footbed designed to fit in the shoe, data indicative of a shoe height, data indicative of a shoe width, or data indicative of a shoe material. As an example, the footbed may be produced such that an outside edge of the footbed matches exactly to the perimeter of the internal shoe lasts in order to provide a perfect fit for the user according to the user's shoes. In an example, the footbed manufacturing system 650 may produce the footbed based on scans of a sock liner of the shoe. The footbed may be produced such that the outside edge of the footbed aligns to a perimeter of the sock liner (e.g., prefabricated footbed) of the shoe. At 606, the footbed manufacturing system 650 may provide the footbed to the footwear brand module 660.

At 607, the footwear brand module 660 may be configured to generate modular footwear system manufacturing specifications (e.g., the data indicative of one or more shoe characteristics and/or specific shoes). At 608, the footwear brand module 660 may provide the modular footwear system manufacturing specifications (e.g., data indicative of one or more shoe characteristics) to the manufacturing system 670.

At 609, the manufacturing system 670 may be configured to generate/produce a modular footwear system according to the footbed manufacturing specifications (e.g., the data indicative of one or more shoe characteristics or specific shoes). As an example, the modular footwear system may comprise one or more footwear components designed according to the footbed manufacturing specifications. The one or more footwear components may comprise the footbed produced by the footbed manufacturing system 650, an upper component, and an outsole component. In an example, the footbed may further comprise one or more attachment interfaces along a perimeter of the footbed. The one or more attachment interfaces may comprise one or more dual-axis locking tabs configured to provide fore-aft and lateral stability between the footbed and the upper component, one or more magnetic aligners configured to align the footbed with the upper component, one or more adaptive fit anchors (e.g., elastic loops) configured to allow an individual wearing the modular footwear system to tension the upper component, and/or one or more anti-rotation features configured to prevent slippage under load (e.g., a person standing up). The one or more magnetic aligners may comprise one or more RFID-based placement guides configured to provide real-time assembly guidance and component verification. The one or more anti-rotation features may comprise one or more key-and-slot designs. The upper component may be configured to couple to a top portion of the footbed via the one or more attachment interfaces. In addition, the outsole component may be configured to couple to a bottom portion of the footbed via the one or more attachment interfaces. In an example, the footbed may further comprise one or more perimeter dovetails (e.g., magnetic alignment wells) configured to align the footbeds with the upper component and outsole component. In an example, the footbed, the upper component, and/or the outsole component may comprise one or more embedded near field communication (NFC) tags and/or QR coding. For example, the footbed, the upper component, and/or the outsole component may may be matched for their intended shell variants. In an example, the QR coding may be used to link a modular footwear system and/or one of its footwear components (e.g., the footbed, the upper component, and/or the outsole component) to an individual (e.g., user profile) and/or order metadata. As an example, the footbed, the upper component, and/or the outsole component may be matched to each other based on the one or more embedded NFC tags and/or the QR coding.

As an example, the manufacturing system 670 may incorporate production planning algorithms, resource allocation procedures, or workflow optimization techniques that maximize manufacturing efficiency while maintaining quality consistency across multiple production orders. The manufacturing system 670 may support integration with existing manufacturing systems, enterprise resource planning platforms, or supply chain management networks that coordinate custom footbed production within broader manufacturing operations. In an example, the manufacturing system 670 may generate production reports, quality documentation, or traceability records that provide comprehensive documentation of manufacturing processes and product characteristics for quality assurance and customer service purposes.

At 610, the manufacturing system 670 may provide the modular footwear system, including the footbed, to the footwear brand module 660. At 611, the footwear brand module 660 may provide the modular footwear system, including the footbed, to the user of the user device 620. As an example, the modular footwear system may be provided to the user pre-assembled or as multiple components to be assembled by the user.

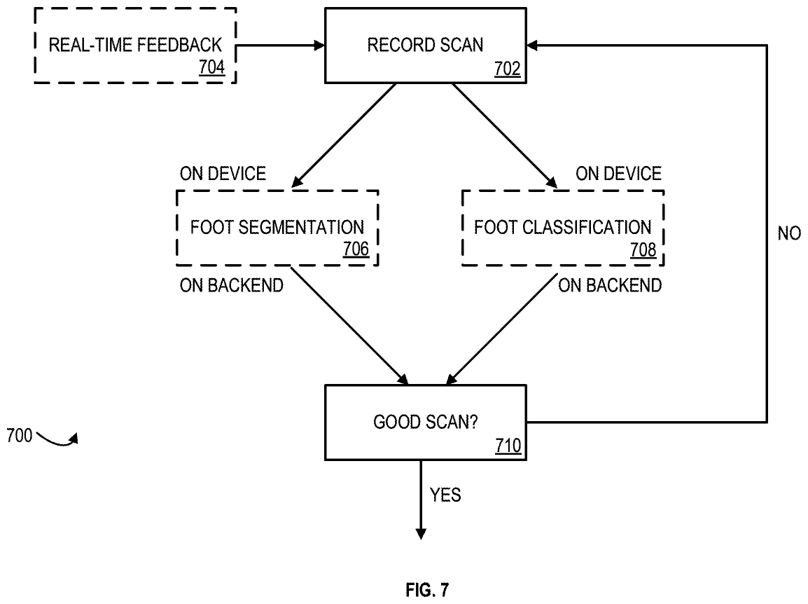

FIG. 7 shows a flowchart of an example scan method 700. At 702, one or more scans of an individual's foot (e.g., left foot or right foot) may be recorded. For example, a user device (e.g., data capture device 101, electronic device 104, etc.) may collect the scans of the individual's foot. In an example, the user device may collect scans of footbeds associated with the individual. In an example, feedback may be received during the scanning process of the individual's foot, at 704. The feedback may indicate that the user device is continuing to collect data, real-time course-correction indicators as the individual scans the extremity, the scanning process terminated based on an error during the scanning process, and/or the scanning process has completed. The scans may be processed in order to determine whether each of the scans satisfy a quality threshold. For example, the scans may be processed via one or more machine learning models (e.g., the machine learning programs/models 159) such as a foot (e.g., extremity) segmentation model, at 706, and/or a foot (e.g., extremity) classification model, at 708. For example, at 706, the foot segmentation model may be configured to process the scans to determine points of a point cloud that make up the foot (e.g., extremity), in each scan, and remove the points within the cloud that do not make up the foot (e.g., extremity). The foot (e.g., extremity) segmentation model may then generate a segmented point cloud, for each scan, based on removing the points within the cloud that do not make up the extremity. At 708, the segmented point cloud of each scan may be processed by the foot (e.g., extremity) classification model, wherein the foot (e.g., extremity) classification model may determine whether each scan satisfies the quality threshold (e.g., edge clarity threshold, proper positioning threshold, etc.). At 710, the scans that do not satisfy the quality threshold may then be retaken, repeating the scanning process starting at 702, until the scans satisfy the quality threshold. In an example, when scans are retaken feedback may be provided showing the individual how to take a successful scan. The scans that satisfy the quality threshold may then be collected and stored in a user profile of the individual. For example, the scans may then be used to generate/produce the pairs of footbeds for the user.

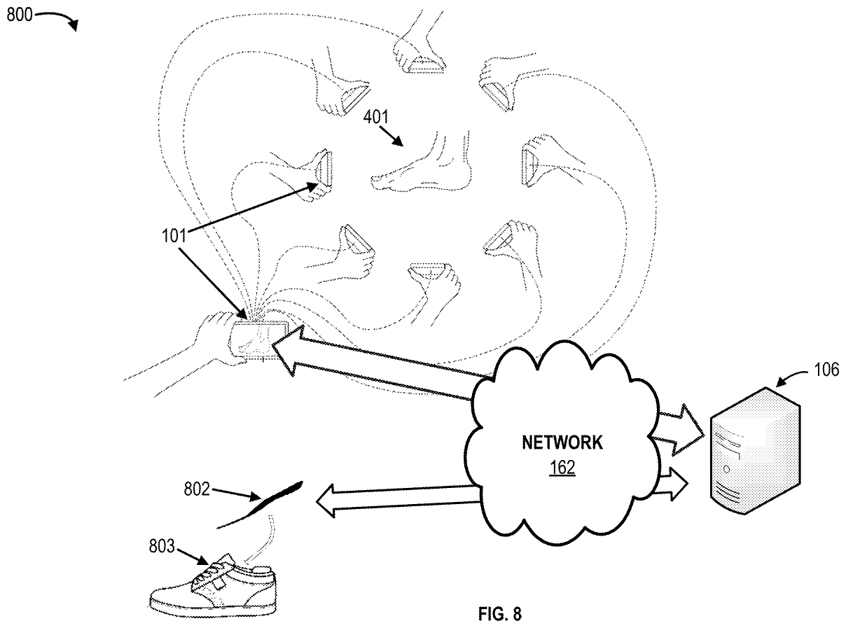

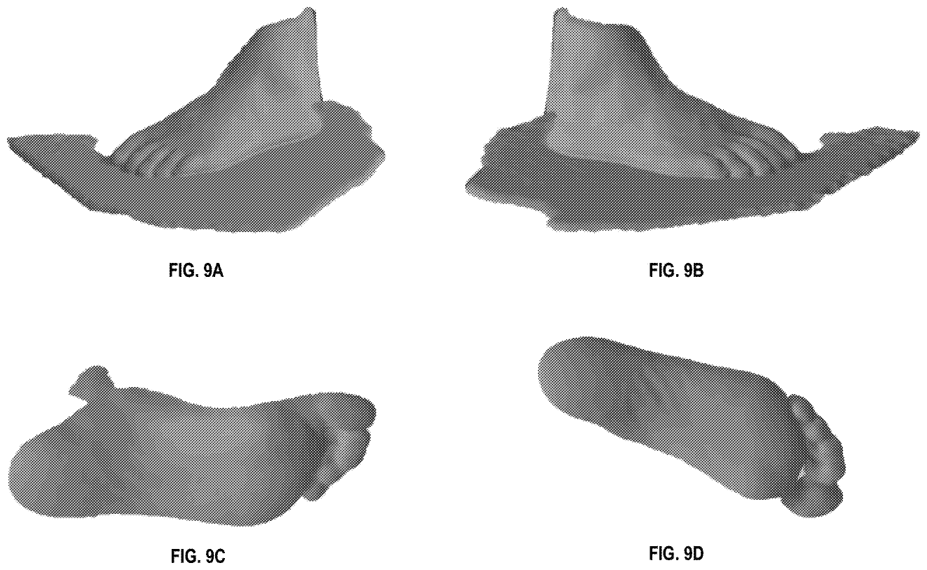

FIG. 8 shows an example system environment 800 for scanning an individual's feet and producing a pair of footbeds. A scanning process may be initiated by the data capture device 101. The data capture device 101 may scan the individual's foot (e.g., extremity) 801 as the individual moves the data capture device 101 in a specified motion based on specific areas of coverage around the foot (e.g., extremity) 801, as shown in FIG. 8. In an example, the data capture device 101 may capture data indicative of one or more positions of the extremity (e.g., foot, hand, arm, leg, etc.) as the individual walks in front of the data capture device 101. For example, the data capture device 101 may be configured to analyze an individual's gait. The data capture device 101 may perform a gait analysis of the individual as the individual walks in front of the data capture device 101 (e.g., towards the data capture device 101 and/or laterally across the data capture device 101). As an example, the data capture device 101 may remain stationary while scanning the individual's foot. Feedback (e.g., haptic feedback, audio feedback, visual feedback, etc.) may be received/output during the scanning process of an individual's foot. The feedback may indicate that the data capture device 101 is continuing to collect data, real-time course-correction indicators as the individual scans the extremity, the scanning process terminated based on an error during the scanning process, and/or the scanning process has completed. The completed scans may be stored in a user profile associated with the individual. For example, as shown in FIGS. 9A-9D, the scans may comprise a three-dimensional rendering of the scanned foot or a portion of the scanned foot. FIGS. 9A and 9C show example scans of a left foot and FIGS. 9B and 9D show example scans of a right foot. The three-dimensional image/rendering of the foot may be output (e.g., displayed) to the individual via the data capture device 101. As shown in FIGS. 9A-9D, the three-dimensional image/rendering may be rotated in the display to display the foot from different angles based on user interaction with the three-dimensional image/rendering via the data capture device 101. As an example, the data capture device 101 may send the completed scans to server 106, via network 162, for further processing and to produce pairs of footbeds 802 based on the scans. In an example, the scans may be used to create shoe-specific footbeds 802 that may be designed/produced according to one or more shoes 803 stored in the user profile of the individual. In an example, the scans and/or the footbeds may be used to create one or more pairs of shoes that may be designed based on the scans and/or based on the footbeds. In an example, the server 106, may create an order for a pair of footbeds based on the scans and send the order to a manufacturer, wherein the manufacturer may produce the footbeds and send the footbeds to the individual. In an example, the server 106 may create an order for one or more pairs of shoes based on the scans and/or based on the generated footbeds and send the order to a manufacturer, wherein the manufacturer may produce the one or more pairs of shoes and send the one or more pairs of shoes to the individual.

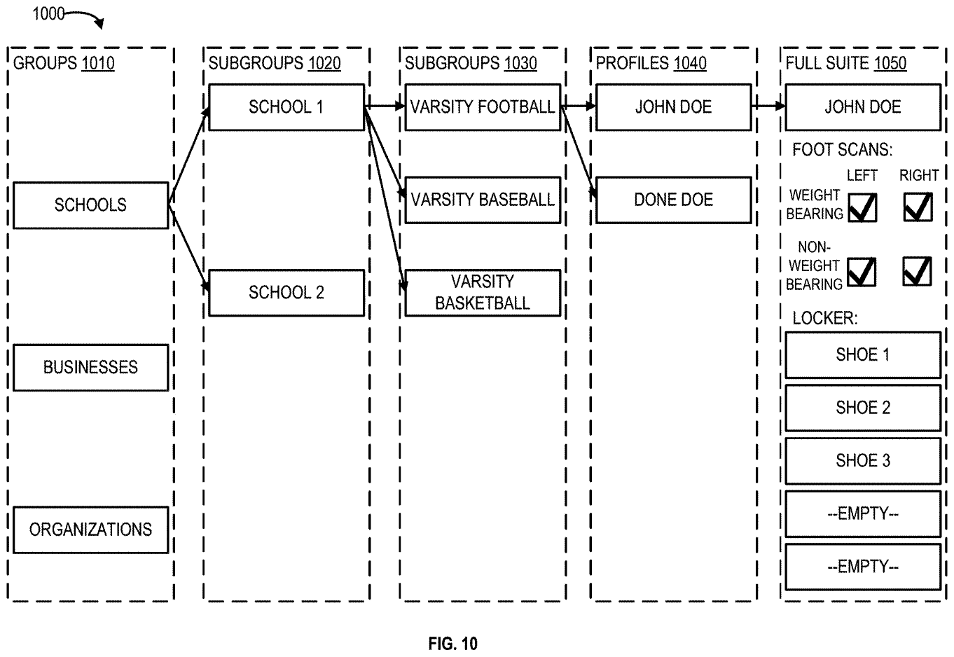

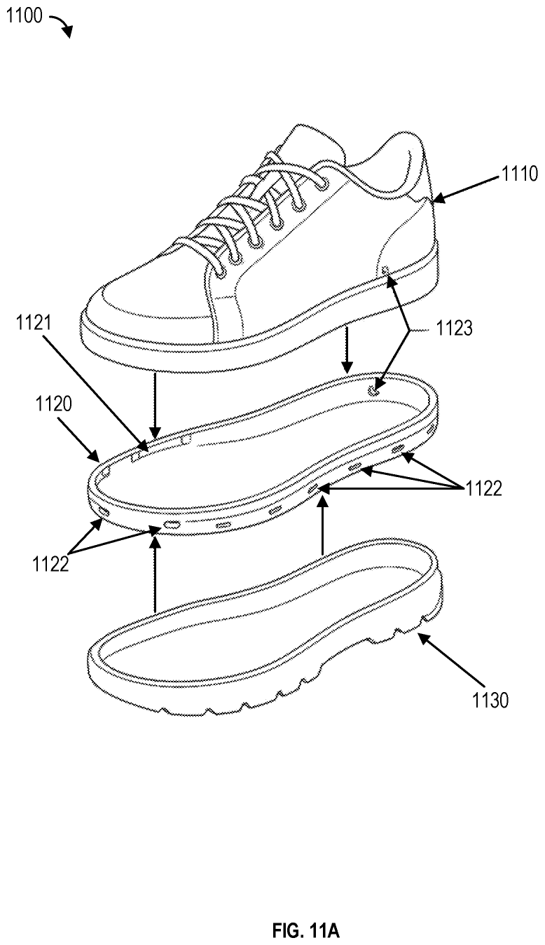

FIG. 10 shows an example operational flow of uploading user profiles that may be associated with different groups or organizations. In an example, one or more groups (e.g., schools, businesses, organizations, associations, etc.) may upload user information associated with one or more individuals of the one or more groups. For example, a group may select that it is associated with a school from a list/database of groups at 1010. At 1020, a specific school (e.g., subgroup) may be selected. In an example, an individual or group may initiate the application, wherein the application may begin at one of the subgroup 1020, 1030 selection steps. At 1030, based the school, the group may choose the particular subgroup (e.g., sport) associated with the user profiles that the school intends to upload. For example, the school may indicate that the user profiles are associated with the school's varsity football sports team. At 1040, the school may indicate, or select, the names of the individuals associated with the user profiles of the varsity football sports team. At 1050, the school may update, or create, the user profile information associated with the selected individual. For example, the user profile information may comprise the saved foot scans and a “locker” comprising the shoes uploaded to the selected individual's user profile. The footbeds may be produced based on the user profile information. As an example, the group may send/upload the group profile information, comprising user profiles associated with one or more individuals, as a single data file. The data file may be stored on a backend device, such as a server or cloud computing device.

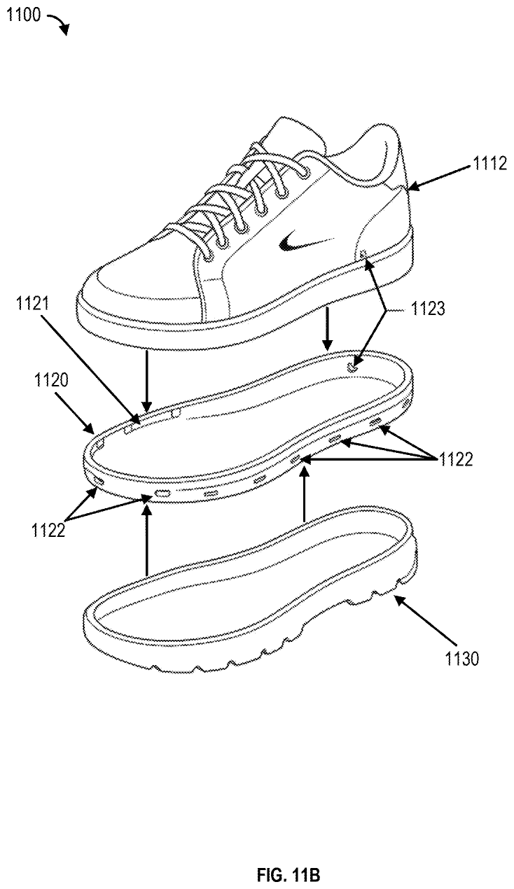

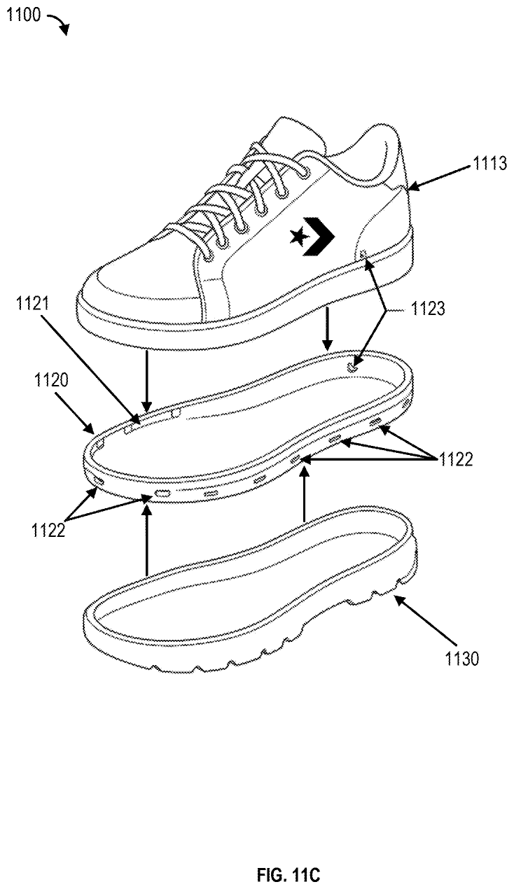

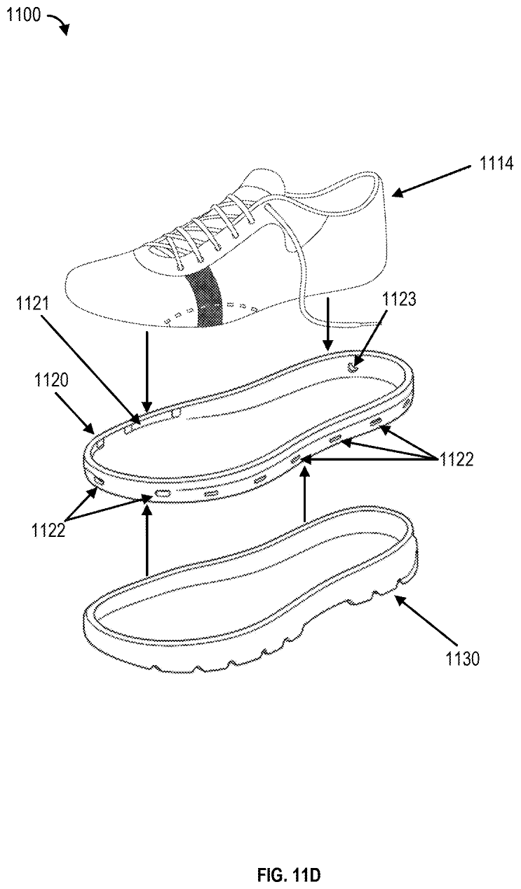

FIGS. 11A-11D show example footwear components of a modular footwear system 1100. The modular footwear system 1100 may comprise one or more footwear components comprising an upper component 1110, a footbed 1122, and an outsole component 1130. As shown in FIG. 11A, the footbed 1122 may comprise one or more attachment interfaces 1121, 1122, 1123 along a perimeter of the footbed 1122. As shown in FIG. 11A, the one or more attachment interfaces 1121, 1122, 1123 may comprise one or more dual-axis locking tabs 1121 configured to provide fore-aft and lateral stability between the footbed 1120 and the upper component 1110, one or more magnetic aligners 1122 configured to align the footbed 1120 with the upper component 1130, one or more adaptive fit anchors 1123 (e.g., elastic loops) configured to allow an individual wearing the modular footwear system 1100 to tension the upper component 1110, and/or one or more anti-rotation features configured to prevent slippage under load (e.g., a person standing up). The one or more magnetic aligners 1122 may comprise one or more RFID-based placement guides configured to provide real-time assembly guidance and component verification. The one or more anti-rotation features may comprise one or more key-and-slot designs. The upper component 1110 may be configured to couple to a top portion of the footbed 1120 via the one or more attachment interfaces 1121, 1122, 1123. In addition, the outsole component 1130 may be configured to couple to a bottom portion of the footbed 1120 via the one or more attachment interfaces 1121, 1122, 1123. In an example, the footbed 1120 may further comprise one or more perimeter dovetails (e.g., magnetic alignment wells) configured to align the footbed 1120 with the upper component 1110 and outsole component 1130. In an example, the upper component 1110, the footbed 1122, and/or the outsole component 1130 may comprise one or more embedded near field communication (NFC) tags and/or QR coding. For example, the upper component 1110, the footbed 1122, and/or the outsole component 1130 may may be matched for their intended shell variants. In an example, the QR coding may be used to link the modular footwear system 1110 and/or one of the upper component 1110, the footbed 1122, and/or the outsole component 1130 to an individual (e.g., user profile) and/or order metadata. As an example, the upper component 1110, the footbed 1122, and/or the outsole component 1130 may be matched to each other based on the one or more embedded NFC tags and/or the QR coding. In an example, a plurality of upper components 1110 and a plurality of outsole components 1130 may be designed and produced to fit one footbed 1122. For example, each of the plurality of upper components 1110 and each of the plurality of outsole components 1130 may be designed to have different logos (e.g., 1112 as shown in FIGS. 11B, 1113 as shown in FIG. 11C), exterior designs (e.g., 1114 as shown in FIG. 11D), etc., enabling a user to interchange the different upper components 1110 and the different outsole components 1130 for attaching to the footbed 1120 in order to customize the modular footwear system 1100 to the user's personal preferences.

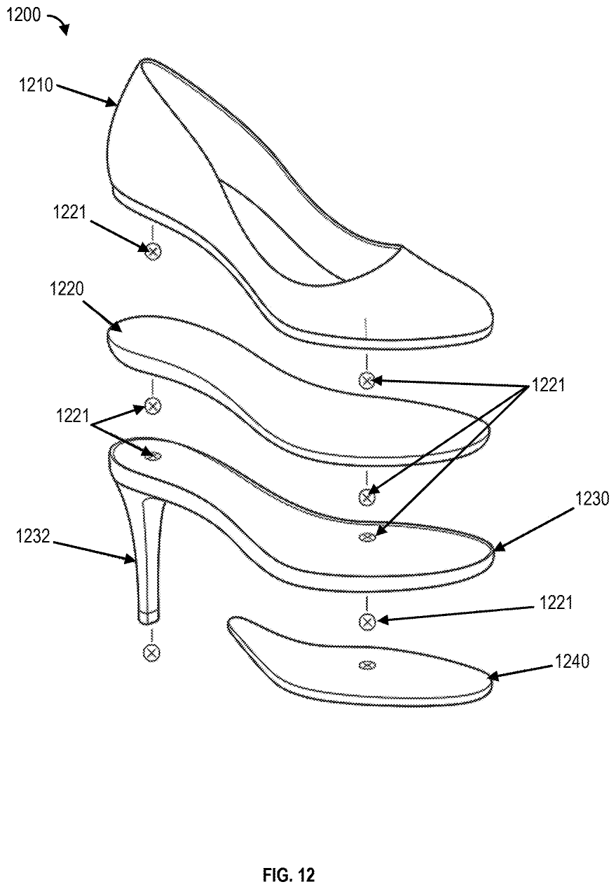

FIG. 12 shows example footwear components of a modular footwear system 1200. As an example, as shown in FIG. 12, the modular footwear system 1200 may comprise a high heel shoe product. The modular footwear system 1200 may comprise one or more footwear components comprising an upper component 1210, a footbed 1222, an upper outsole component 1230, and a lower outsole component 1240. The footbed 1222 may comprise one or more attachment interfaces 1221. The one or more attachment interfaces 1221 may comprise one or more dual-axis locking tabs configured to provide fore-aft and lateral stability between the footbed and the upper component, one or more magnetic aligners configured to align the footbed with the upper component, one or more adaptive fit anchors (e.g., elastic loops) configured to allow an individual wearing the modular footwear system to tension the upper component, and/or one or more anti-rotation features configured to prevent slippage under load (e.g., a person standing up).

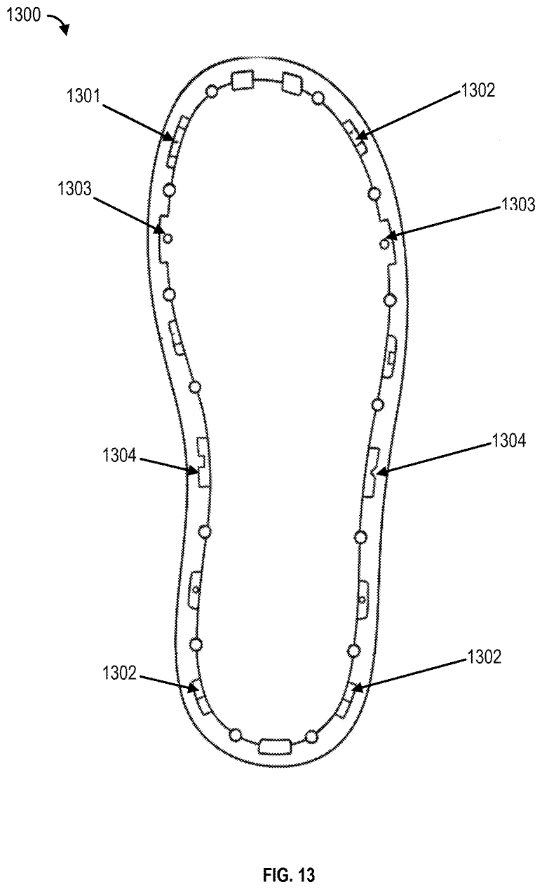

FIG. 13 shows an example footbed component 1300 of a modular footwear system. As shown in FIG. 13, the footbed component 1300 may comprise one or more attachment interfaces 1301, 1302, 1303, 1304 along a perimeter of the footbed component 1300. The one or more attachment interfaces 1301, 1302, 1303, 1304 may comprise one or more dual-axis locking tabs 1301 configured to provide fore-aft and lateral stability between the footbed component 1300 and an upper component of the modular footwear system, one or more magnetic aligners 1302 configured to align the footbed 1300 with the upper component, one or more adaptive fit anchors 1303 (e.g., elastic loops) configured to allow an individual wearing the modular footwear system to tension the upper component, and/or one or more anti-rotation features 1304 configured to prevent slippage under load (e.g., a person standing up). The one or more magnetic aligners 1302 may comprise one or more RFID-based placement guides configured to provide real-time assembly guidance and component verification. The one or more anti-rotation features 1304 may comprise one or more key-and-slot designs. The upper component may be configured to couple to a top portion of the footbed 1300 via the one or more attachment interfaces 1301, 1302, 1303, 1304. In addition, the modular footwear system may comprise an outsole component that may be configured to couple to a bottom portion of the footbed 1300 via the one or more attachment interfaces 1301, 1302, 1303, 1304.

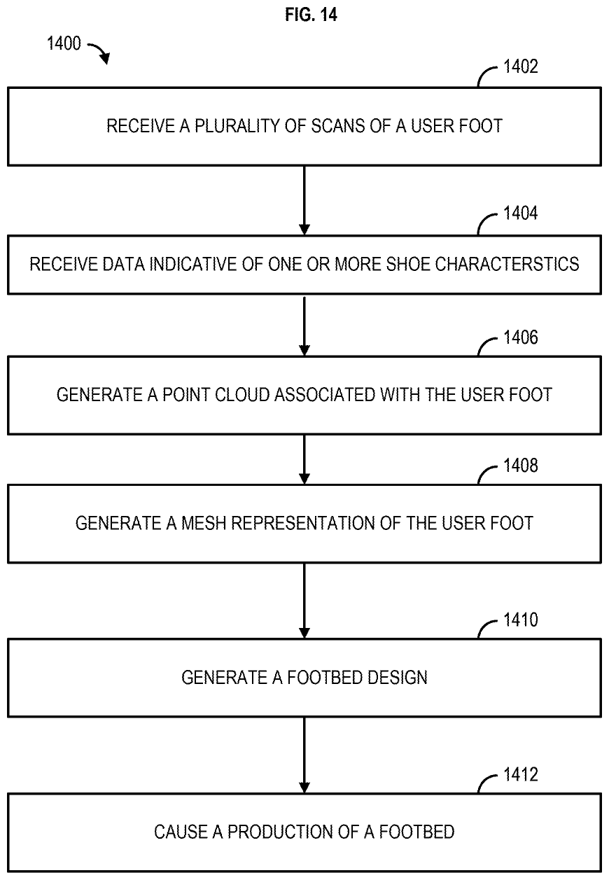

FIG. 14 shows a flowchart of an example method 1400 for producing a footbed based on a plurality of scans of a user's foot. Method 1400 may be implemented by a user device (e.g., data capture device 101, the electronic device 104, server 106, etc.). At step 1402, a plurality of scans of a user foot may be received. For example, the plurality of scans of the user foot may be received by a user device (e.g., data capture device 101, the electronic device 104, server 106, etc.) from one or more scanning devices. In an example, a user profile of a plurality of user profiles may be determined. For example, each user profile of the plurality of user profiles may comprise data associated with one or more shoes associated with an individual user. Each user profile may include one or more footbeds generated based on a plurality of scans of one or more feet of a user and the data associated with the one or more shoes associated with the user. The user foot may comprise a left foot of the user or a right foot of the user. The one or more scanning devices may comprise one or more of an imaging device, a camera, a depth camera, or a LiDAR sensor. In an example, the one or more scanning devices may be configured to capture data indicative of one or more positions of the user foot as the user walks in front of the one or more scanning devices. For example, the user device may be configured to analyze the user's gait. The user device may perform a gait analysis of the user as the user walks in front of the user device (e.g., towards the user device and/or laterally across the user device). For example, the one or more positions may comprise one or more of a weight-bearing position or a non-weight-bearing position. In an example, feedback associated with each scan of the plurality of scans may be determined. The feedback may comprise one or more of haptic feedback, audio feedback, visual feedback, and the like. The feedback may be indicative of one or more of: the user device is continuing to collect data, real-time course-correction indicators as the individual scans the extremity, a scanning process terminated based on an error during a scanning process, or a scanning process has completed. In an example, the feedback may be determined based on an application of an object detection model and a machine learning segmentation model to the first plurality of scans.

At step 1404, data indicative of one or more shoe characteristics may be received. For example, the user device (e.g., data capture device 101, the electronic device 104, server 106, etc.) may receive the data indicative of the one or more shoe characteristics. The data indicative of the one or more shoe characteristics comprise one or more of data indicative of one or more scans of an interior of a shoe, data indicative of an interior shape of the shoe, data indicative of one or more scans of the footbed designed to fit in the shoe, data indicative of a shape of the footbed designed to fit in the shoe, data indicative of a shoe height, data indicative of a shoe width, or data indicative of a shoe material.

At step 1406 a point cloud associated with the user foot may be generated. For example, the user device (e.g., data capture device 101, the electronic device 104, server 106, etc.) may generate the point cloud associated with the user foot based on data indicative of the plurality of scans. For example, the point cloud associated with the user foot may be generated based on applying a segmentation model to each scan of the plurality of scans. The segmentation model may be configured to process the plurality of scans to determine points of the point cloud that make up the user foot, in each scan, and remove points of the point cloud that do not make up the user foot. The segmentation model may then generate a segmented point cloud, for each scan, based on removing the points of the point cloud that do not make up the user foot.

At step 1408, a mesh representation of the user foot may be generated. For example, the user device (e.g., data capture device 101, the electronic device 104, server 106, etc.) may generate the mesh representation of the user foot based on the point cloud. For example, the segmented point cloud may be provided to a classification model. Based on an application of the classification model to the segmented point cloud, it may be determined that data associated with a first portion of the plurality of scans satisfies a threshold and data associated with a second portion of the plurality of scans does not satisfy the threshold. The second portion of the plurality of scans may be retaken until each scan of the second portion of the plurality of scans satisfies the threshold based on the data associated with the second portion of the plurality of scans not satisfying the threshold. The mesh representation of the user foot may be generated based on the first portion of the plurality of scans and the retaken second portion of the plurality of scans. In an example, the first portion of the plurality of scans and the retaken second portion of the plurality of scans may be stored in a database in a user profile. In an example, the mesh representation may be stored in the databased in the user profile.

At step 1410, a footbed design may be generated. For example, the user device (e.g., data capture device 101, the electronic device 104, server 106, etc.) may generate the footbed design based on the mesh representation of the user foot and the data indicative of the one or more shoe characteristics. As an example, the footbed design may be generated according to individual user foot characteristics captured by the plurality of scans of the user foot based on one or more algorithmic surface optimization techniques. For example, the footbed may be designed and produced such that the outside edge of the footbed match exactly to the perimeter of internal shoe lasts in order to provide a perfect fit for the user for the user's shoe.

At step 1412, a footbed may be produced according to the footbed design. For example, the user device (e.g., data capture device 101, the electronic device 104, server 106, etc.) may cause the footbed to be produced according to the footbed design. For example, the footbed may comprise one or more attachment interfaces along a perimeter of the footbed configured to couple the footbed with one or more footwear components associated with the one or more shoe characteristics. As example, a modular footwear system comprising one or more footwear components may be designed and produced based on the footbeds. For example, the one or more footwear components of the modular footwear system may comprise the footbed produced based on the plurality of scans, an upper component, and an outsole component. The one or more attachment interfaces may comprise one or more dual-axis locking tabs configured to provide fore-aft and lateral stability between the footbed and the upper component, one or more magnetic aligners configured to align the footbed with the upper component, one or more adaptive fit anchors (e.g., elastic loops) configured to allow an individual wearing the modular footwear system to tension the upper component, and/or one or more anti-rotation features configured to prevent slippage under load (e.g., a person standing up). The one or more magnetic aligners may comprise one or more RFID-based placement guides configured to provide real-time assembly guidance and component verification. The one or more anti-rotation features may comprise one or more key-and-slot designs. The upper component may be configured to couple to a top portion of the footbed via the one or more attachment interfaces. In addition, the outsole component may be configured to couple to a bottom portion of the footbed via the one or more attachment interfaces. In an example, the footbed may further comprise one or more perimeter dovetails (e.g., magnetic alignment wells) configured to align the footbeds with the upper component and outsole component. In an example, the footbed, the upper component, and/or the outsole component may comprise one or more embedded near field communication (NFC) tags and/or QR coding. For example, the footbed, the upper component, and/or the outsole component may may be matched for their intended shell variants. In an example, the QR coding may be used to link a modular footwear system and/or one of its footwear components (e.g., the footbed, the upper component, and/or the outsole component) to an individual (e.g., user profile) and/or order metadata. As an example, the footbed, the upper component, and/or the outsole component may be matched to each other based on the one or more embedded NFC tags and/or the QR coding.

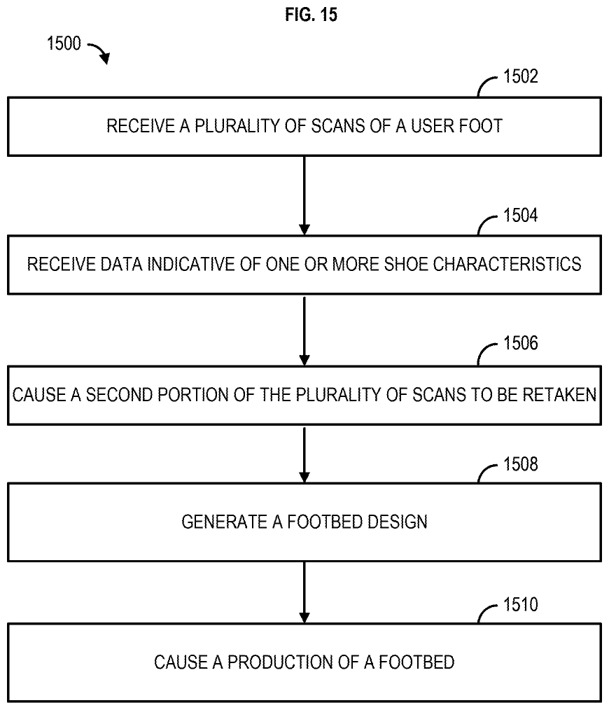

FIG. 15 shows a flowchart of an example method 1500 for producing a footbed based on a plurality of scans of a user's foot. Method 1500 may be implemented by a user device (e.g., data capture device 101, the electronic device 104, server 106, etc.). At step 1502, a first plurality of scans of a user foot may be received. For example, the plurality of scans of the user foot may be received by a user device (e.g., data capture device 101, the electronic device 104, server 106, etc.) from one or more scanning devices. In an example, a user profile of a plurality of user profiles may be determined. For example, each user profile of the plurality of user profiles may comprise data associated with one or more shoes associated with an individual user. Each user profile may include one or more footbeds generated based on a plurality of scans of one or more feet of a user and the data associated with the one or more shoes associated with the user. The user foot may comprise one or more of a left foot of the user or a right foot of the user. The one or more scanning devices may comprise one or more of an imaging device, a camera, a depth camera, or a LiDAR sensor. In an example, the one or more scanning devices may be configured to capture data indicative of one or more positions of the user foot as the user walks in front of the one or more scanning devices. For example, the user device may be configured to analyze an user's gait. The user device may perform a gait analysis of the user as the user walks in front of the user device (e.g., towards the user device and/or laterally across the user device). For example, the one or more positions may comprise one or more of a weight-bearing position or a non-weight-bearing position. In an example, feedback associated with each scan of the first plurality of scans may be determined. The feedback may comprise one or more of haptic feedback, audio feedback, visual feedback, and the like. The feedback may be indicative of one or more of: the user device is continuing to collect data, real-time course-correction indicators as the individual scans the extremity, a scanning process terminated based on an error during a scanning process, or a scanning process has completed. In an example, the feedback may be determined based on an application of an object detection model and a machine learning segmentation model to the first plurality of scans.

At step 1504, data indicative of one or more shoe characteristics may be received. For example, the user device (e.g., data capture device 101, the electronic device 104, server 106, etc.) may receive the data indicative of the one or more shoe characteristics. The data indicative of the one or more shoe characteristics comprise one or more of data indicative of one or more scans of an interior of a shoe, data indicative of an interior shape of the shoe, data indicative of one or more scans of the footbed designed to fit in the shoe, data indicative of a shape of the footbed designed to fit in the shoe, data indicative of a shoe height, data indicative of a shoe width, or data indicative of a shoe material.

At step 1506, a second portion of the plurality of scans may be retaken. For example, the user device (e.g., data capture device 101, the electronic device 104, server 106, etc.) may cause the second portion of the plurality of scans to be retaken based on data associated with a first portion of the plurality of scans satisfying a threshold and data associated with a second portion of the plurality of scans not satisfying the threshold. As an example, a first machine learning model and a second machine learning model may be applied to each scan of the plurality of scans to determine that the data associated with the first portion of the plurality of scans satisfies the threshold and that the data associated with the second portion of the plurality of scans does not satisfy the threshold. The first machine learning model may comprise a segmentation model and the second machine learning model may comprise a classification model. The first machine learning model may be applied to the plurality of scans to determine points of a point cloud that make up the user foot and remove points of the point cloud that do not make up the user foot. Based on removing the points of the point cloud that do not make up the user foot, a segmented point cloud may be generated. The second machine learning model may be applied to the segmented point cloud to determine that the data associated with the first portion of the plurality of scans satisfies the threshold and the data associated with the second portion of the plurality of scans does not satisfy the threshold. In an example, the first portion of the plurality of scans, the second portion of the plurality of scans, and the retaken second portion of the plurality of scans may be sent to a computing device. For example, the computing device may comprise a server (e.g., server 106). The first portion of the plurality of scans, the second portion of the plurality of scans, and the retaken second portion of the plurality of scans may be stored in a database of the computing device as labeled training data for training the first machine learning model and the second machine learning model. In an example, the first portion of the plurality of scans and the retaken second portion of the plurality of scans may be stored in the databased of the computing device in a user profile associated with the user.

At step 1508, a footbed design may be generated. For example, user device (e.g., data capture device 101, the electronic device 104, server 106, etc.) may generate the footbed design based on the first portion of the plurality of scans and the retaken second portion of the plurality of scans and based on the data indicative of the one or more shoe characteristics. As an example, the footbed design may be generated according to individual user foot characteristics captured by the plurality of scans of the user foot based on one or more algorithmic surface optimization techniques. For example, the footbed may be designed and produced such that the outside edge of the footbed match exactly to the perimeter of internal shoe lasts in order to provide a perfect fit for the user for the user's shoe.

At step 1510, a footbed may be produced according to the footbed design. For example, the user device (e.g., data capture device 101, the electronic device 104, server 106, etc.) may cause the footbed to be produced according to the footbed design. The footbed may comprise one or more attachment interfaces along a perimeter of the footbed configured to couple the footbed with one or more footwear components associated with the one or more shoe characteristics. As example, a modular footwear system comprising one or more footwear components may be designed and produced based on the footbeds. For example, the one or more footwear components of the modular footwear system may comprise the footbed produced based on the plurality of scans, an upper component, and an outsole component. The one or more attachment interfaces may comprise one or more dual-axis locking tabs configured to provide fore-aft and lateral stability between the footbed and the upper component, one or more magnetic aligners configured to align the footbed with the upper component, one or more adaptive fit anchors (e.g., elastic loops) configured to allow an individual wearing the modular footwear system to tension the upper component, and/or one or more anti-rotation features configured to prevent slippage under load (e.g., a person standing up). The one or more magnetic aligners may comprise one or more RFID-based placement guides configured to provide real-time assembly guidance and component verification. The one or more anti-rotation features may comprise one or more key-and-slot designs. The upper component may be configured to couple to a top portion of the footbed via the one or more attachment interfaces. In addition, the outsole component may be configured to couple to a bottom portion of the footbed via the one or more attachment interfaces. In an example, the footbed may further comprise one or more perimeter dovetails (e.g., magnetic alignment wells) configured to align the footbeds with the upper component and outsole component. In an example, the footbed, the upper component, and/or the outsole component may comprise one or more embedded near field communication (NFC) tags and/or QR coding. For example, the footbed, the upper component, and/or the outsole component may may be matched for their intended shell variants. In an example, the QR coding may be used to link a modular footwear system and/or one of its footwear components (e.g., the footbed, the upper component, and/or the outsole component) to an individual (e.g., user profile) and/or order metadata. As an example, the footbed, the upper component, and/or the outsole component may be matched to each other based on the one or more embedded NFC tags and/or the QR coding.

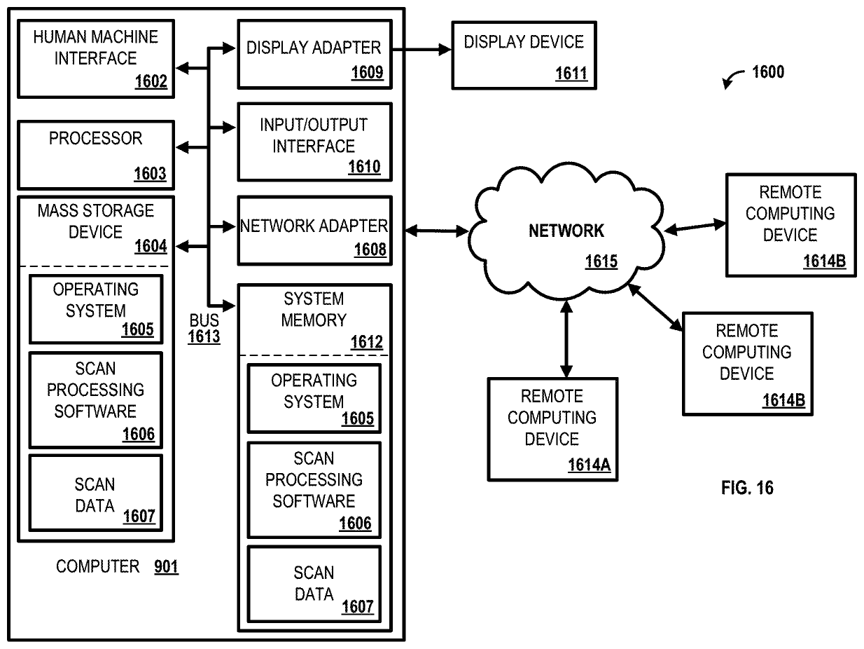

The methods and systems can be implemented on a computer 1601 as illustrated in FIG. 16 and described below. By way of example, the data capture device 101, the display device 102, the electronic device 104 and/or the server 106 of FIG. 1 and/or the can be a computer 1601 as illustrated in FIG. 16. Similarly, the methods and systems disclosed can utilize one or more computers to perform one or more functions in one or more locations. FIG. 16 is a block diagram illustrating an example operating environment 1600 for performing the disclosed methods. This example operating environment 1600 is only an example of an operating environment and is not intended to suggest any limitation as to the scope of use or functionality of operating environment architecture. Neither should the operating environment 1600 be interpreted as having any dependency or requirement relating to any one or combination of components illustrated in the example operating environment 1600.

The present methods and systems can be operational with numerous other general purpose or special purpose computing system environments or configurations. Examples of well-known computing systems, environments, and/or configurations that can be suitable for use with the systems and methods comprise, but are not limited to, personal computers, server computers, laptop devices, and multiprocessor systems. Additional examples comprise set top boxes, programmable consumer electronics, network PCs, minicomputers, mainframe computers, distributed computing environments that comprise any of the above systems or devices, and the like.

The processing of the disclosed methods and systems can be performed by software components. The disclosed systems and methods can be described in the general context of computer-executable instructions, such as program modules, being executed by one or more computers or other devices. Generally, program modules comprise computer code, routines, programs, objects, components, data structures, and/or the like that perform particular tasks or implement particular abstract data types. The disclosed methods can also be practiced in grid-based and distributed computing environments where tasks are performed by remote processing devices that are linked through a communications network. In a distributed computing environment, program modules can be located in local and/or remote computer storage media such as memory storage devices.

Further, one skilled in the art will appreciate that the systems and methods disclosed herein can be implemented via a general-purpose computing device in the form of a computer 1601. The computer 1601 can comprise one or more components, such as one or more processors 1603, a system memory 1612, and a bus 1613 that couples various components of the computer 1601 comprising the one or more processors 1603 to the system memory 1612. The system can utilize parallel computing.

The bus 1613 can comprise one or more of several possible types of bus structures, such as a memory bus, memory controller, a peripheral bus, an accelerated graphics port, or local bus using any of a variety of bus architectures. By way of example, such architectures can comprise an Industry Standard Architecture (ISA) bus, a Micro Channel Architecture (MCA) bus, an Enhanced ISA (EISA) bus, a Video Electronics Standards Association (VESA) local bus, an Accelerated Graphics Port (AGP) bus, and a Peripheral Component Interconnects (PCI), a PCI-Express bus, a Personal Computer Memory Card Industry Association (PCMCIA), Universal Serial Bus (USB) and the like. The bus 1613, and all buses specified in this description can also be implemented over a wired or wireless network connection and one or more of the components of the computer 1601, such as the one or more processors 1603, a mass storage device 1604, an operating system 1605, scan processing software 1606, scan data 1607, a network adapter 1608, the system memory 1612, an Input/Output Interface 1610, a display adapter 1609, a display device 1611, and a human machine interface 1602, can be contained within one or more remote computing devices 1614A-1614C at physically separate locations, connected through buses of this form, in effect implementing a fully distributed system.

The computer 1601 typically comprises a variety of computer readable media. Examples of readable media can be any available media that is accessible by the computer 1601 and comprises, for example and not meant to be limiting, both volatile and non-volatile media, removable and non-removable media. The system memory 1612 can comprise computer readable media in the form of volatile memory, such as random access memory (RAM), and/or non-volatile memory, such as read only memory (ROM). The system memory 1612 typically can comprise data such as the scan data 1607 and/or program modules such as the operating system 1605 and the scan processing software 1606 that are accessible to and/or are operated on by the one or more processors 1603.

In another aspect, the computer 1601 can also comprise other removable/non-removable, volatile/non-volatile computer storage media. The mass storage device 1604 can provide non-volatile storage of computer code, computer readable instructions, data structures, program modules, and other data for the computer 1601. For example, the mass storage device 1604 can be a hard disk, a removable magnetic disk, a removable optical disk, magnetic cassettes or other magnetic storage devices, flash memory cards, CD-ROM, digital versatile disks (DVD) or other optical storage, random access memories (RAM), read only memories (ROM), electrically erasable programmable read-only memory (EEPROM), and the like.

Optionally, any number of program modules can be stored on the mass storage device 1604, such as, by way of example, the operating system 1605 and the scan processing software 1606. One or more of the operating system 1605 and the scan processing software 1606 (or some combination thereof) can comprise elements of the programming and the scan processing software 1606. The scan data 1607 can also be stored on the mass storage device 1604. The scan data 1607 can be stored in any of one or more databases known in the art. Examples of such databases comprise, DB2®, Microsoft® Access, Microsoft® SQL Server, Oracle®, mySQL, PostgreSQL, and the like. The databases can be centralized or distributed across multiple locations within the network 1615.

In another aspect, the user can enter commands and information into the computer 1601 via an input device (not shown). Examples of such input devices comprise, but are not limited to, a keyboard, pointing device (e.g., a computer mouse, remote control), a microphone, a joystick, a scanner, tactile input devices such as gloves, and other body coverings, motion sensor, and the like These and other input devices can be connected to the one or more processors 1603 via the human machine interface 1602 that is coupled to the bus 1613, but can be connected by other interface and bus structures, such as a parallel port, game port, an IEEE 1394 Port (also known as a Firewire port), a serial port, a network adapter 1608, and/or a universal serial bus (USB).

In yet another aspect, the display device 1611 can also be connected to the bus 1613 via an interface, such as the display adapter 1609. It is contemplated that the computer 1601 can have more than one display adapter 1609 and the computer 1601 can have more than one display device 1611. For example, the display device 1611 can be a monitor, an LCD (Liquid Crystal Display), light emitting diode (LED) display, television, smart lens, smart glass, and/or a projector. In addition to the display device 1611, other output peripheral devices can comprise components such as speakers (not shown) and a printer (not shown) which can be connected to the computer 1601 via an Input/Output Interface 1610. Any step and/or result of the methods can be output in any form to an output device. Such output can be any form of visual representation, comprising, but not limited to, textual, graphical, animation, audio, tactile, and the like. The display device 1611 and the computer 1601 can be part of one device, or separate devices.

The computer 1601 can operate in a networked environment using logical connections to one or more remote computing devices 1614A-1614C. By way of example, a remote computing device 1614A-1614C can be a personal computer, computing station (e.g., workstation), portable computer (e.g., laptop, mobile phone, tablet device), smart device (e.g., smartphone, smart watch, activity tracker, smart apparel, smart accessory), security and/or monitoring device, a server, a router, a network computer, a peer device, edge device or other common network node, and so on. Logical connections between the computer 1601 and a remote computing device 1614A-1614C can be made via a network 1615, such as a local area network (LAN) and/or a general wide area network (WAN). Such network connections can be through the network adapter 1608. The network adapter 1608 can be implemented in both wired and wireless environments. Such networking environments are conventional and commonplace in dwellings, offices, enterprise-wide computer networks, intranets, and the Internet.

For purposes of illustration, application programs and other executable program components such as the operating system 1605 are illustrated herein as discrete blocks, although it is recognized that such programs and components can reside at various times in different storage components of the computing device 1601, and are executed by the one or more processors 1603 of the computing device 1601. An implementation of the scan processing software 1606 can be stored on or transmitted across some form of computer readable media. Any of the disclosed methods can be performed by computer readable instructions embodied on computer readable media. Computer readable media can be any available media that can be accessed by a computer. By way of example and not meant to be limiting, computer readable media can comprise “computer storage media” and “communications media.” “Computer storage media” can comprise volatile and non-volatile, removable and non-removable media implemented in any methods or technology for storage of information such as computer readable instructions, data structures, program modules, or other data. Example computer storage media can comprise RAM, ROM, EEPROM, flash memory or other memory technology, CD-ROM, digital versatile disks (DVD) or other optical storage, magnetic cassettes, magnetic tape, magnetic disk storage or other magnetic storage devices, or any other medium which can be used to store the desired information and which can be accessed by a computer.

The methods and systems can employ artificial intelligence (AI) techniques such as machine learning and iterative learning. Examples of such techniques comprise, but are not limited to, expert systems, case based reasoning, Bayesian networks, behavior based AI, neural networks, fuzzy systems, evolutionary computation (e.g. genetic algorithms), swarm intelligence (e.g. ant algorithms), and hybrid intelligent systems (e.g. Expert inference rules generated through a neural network or production rules from statistical learning).

While the methods and systems have been described in connection with preferred embodiments and specific examples, it is not intended that the scope be limited to the particular embodiments set forth, as the embodiments herein are intended in all respects to be illustrative rather than restrictive.

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that an order be inferred, in any respect. This holds for any possible non-express basis for interpretation, such as: matters of logic with respect to arrangement of steps or operational flow; plain meaning derived from grammatical organization or punctuation; the number or type of embodiments described in the specification.

It will be apparent to those skilled in the art that various modifications and variations may be made without departing from the scope or spirit. Other configurations will be apparent to those skilled in the art from consideration of the specification and practice described herein. It is intended that the specification and described configurations be considered as examples only, with a true scope and spirit being indicated by the following claims.

What is claimed is:

1. A modular footwear system comprising:
a footbed comprising one or more attachment interfaces along a perimeter of the footbed, wherein the footbed is generated according to a footbed design, wherein the footbed design is generated according to individual foot characteristics captured by a plurality of scans of a user foot;
an upper configured to couple with the footbed via the one or more attachment interfaces; and
an outsole configured to couple with the footbed via the one or more attachment interfaces, wherein the footbed is configured as an anchor between the upper and the outsole.

2. The modular footwear system of claim 1, wherein the one or more attachment interfaces comprise one or more dual-axis locking tabs configured to provide fore-aft and lateral stability between the footbed and the upper.

3. The modular footwear system of claim 1, wherein the one or more attachment interfaces comprise one or more magnetic aligners configured to align the footbed with the upper.

4. The modular footwear system of claim 3, wherein the one or more magnetic aligners comprise one or more RFID-based placement guides configured to provide real-time assembly guidance and component verification.

5. The modular footwear system of claim 1, wherein the footbed further comprises one or more anti-rotation features along the perimeter of the footbed, wherein the one or more anti-rotation features comprise one or more key-and-slot designs.

6. The modular footwear system of claim 1, wherein the footbed further comprises one or more adaptive fit anchors.

7. The modular footwear system of claim 1, wherein one or more of the footbed, the upper, or the outsole comprise one or more embedded NFC tags or QR coding.

8. The modular footwear system of claim 7, wherein one or more of the footbed, the upper, or the outsole is matched to one or more of the footbed, the upper, or the outsole based on the one or more embedded NFC tags or the QR coding.

9. A method comprising:
receiving, by a device, from one or more scanning devices, a plurality of scans of a user foot;
receiving data indicative of one or more shoe characteristics;
generating, based on data indicative of the plurality of scans, a point cloud associated with the user foot;
generating, based on the point cloud, a mesh representation of the user foot;
generating, based on the mesh representation of the user foot and the data indicative of the one or more shoe characteristics, a footbed design; and
causing a production of a footbed according to the footbed design, wherein the footbed comprises one or more attachment interfaces configured to couple the footbed with one or more footwear components associated with the one or more shoe characteristics.

10. The method of claim 9, wherein the one or more scanning devices comprise one or more of an imaging device, a camera, a depth camera, an infrared sensor, or a LiDAR sensor.

11. The method of claim 9, wherein the data indicative of the one or more shoe characteristics comprise one or more of data indicative of one or more scans of an interior of a shoe, data indicative of an interior shape of the shoe, data indicative of one or more scans of the footbed designed to fit in the shoe, data indicative of a shape of the footbed designed to fit in the shoe, data indicative of a shoe height, data indicative of a shoe width, or data indicative of a shoe material.

12. The method of claim 9, wherein generating, based on the data indicative of the plurality of scans, the point cloud associated with the user foot comprises generating, based on an application of a segmentation model to each scan of the plurality of scans, a segmented point cloud associated with the user foot.

13. The method of claim 12, wherein generating, based on the point cloud, the mesh representation of the user foot comprises:
determining, based on an application of a classification model to the segmented point cloud, data associated with a first portion of the plurality of scans satisfies a threshold and data associated with a second portion of the plurality of scans does not satisfy the threshold;
causing, based on the data associated with the second portion of the plurality of scans not satisfying the threshold, the second portion of the plurality of scans to be retaken until each scan of the second portion of the plurality of scans satisfies the threshold; and
generating, based on the first portion of the plurality of scans and the retaken second portion of the plurality of scans, the mesh representation of the user foot.

14. The method of claim 9, wherein generating, based on the mesh representation of the user foot and the data indicative of the one or more shoe characteristics, the footbed design comprises generating, based on one or more algorithmic surface optimization techniques, the footbed design according to individual user foot characteristics captured by the plurality of scans of the user foot.

15. The method of claim 9, wherein the one or more attachment interfaces comprise one or more of dual-axis locking tabs, magnetic aligners, and anti-rotation features positioned along a perimeter of the footbed.

16. The method of claim 9, wherein the one or more footwear components comprise one or more of an upper and an outsole.

17. The method of claim 9, further comprising outputting the mesh representation of the user foot.

18. The method of claim 9, further comprising determining, based on an application of an object detection model and a machine learning segmentation model to each scan of the plurality of scans of the user foot, feedback associated with each scan.

19. The method of claim 18, wherein the feedback is indicative of one or more of: the device is continuing to collect data; real-time course-correction indicators as an individual scans the user foot; a scanning process terminated based on an error during the scanning process; or a scanning process has completed.

20. A method comprising:
receiving, by a device, scan data of a user foot and scan data of a shoe;
generating, based on the scan data of the user foot, a first mesh representation of the user foot;
generating, based on the scan data of the shoe, a second mesh representation of the shoe; and
generating, based on the first mesh representation and the second mesh representation, a footbed, wherein the footbed is configured to fit in an interior portion of the shoe according to the user foot.
